(19) United States
(12) Patent Application Publication
(10) Pub. No.: US 2026/0017954 A1
(43) Pub. Date: Jan. 15, 2026

(54) PERFORMING OBJECT PERCEPTION USING LOCATION-BASED KNOWLEDGE FOR AUTONOMOUS SYSTEMS AND APPLICATIONS

(71) Applicant: NVIDIA Corporation, Santa Clara, CA (US)

(72) Inventors: Wongun Choi, Los Altos, CA (US); Zhengjia Huang, San Jose, CA (US)

(21) Appl. No.: 18/767,701

(22) Filed: Jul. 9, 2024

(51) Int. Cl. G06V 20/58; B60W 30/06; B60W 60/00; G06T 7/246; G06T 7/73; G06V 10/25; G06V 10/776

(52) U.S. Cl. CPC G06V 20/586; G06T 7/246; G06T 7/73; G06V 10/25; G06V 10/776; B60W 30/06; B60W 60/001; B60W 2556/40; G06T 2207/30261; G06T 2207/30264; G06V 2201/07

(57) ABSTRACT

In various examples, certain objects commonly found in predictable locations of an environment may be more reliably perceived by leveraging known information related to the locations and/or the objects themselves. For instance, the disclosed systems and methods may determine locations of target areas within a coordinate system associated with a target region in an environment, and use the target areas to detect and track certain objects that may be otherwise difficult to perceive. As an example, a target region may be a parking space for a machine and the coordinate system may indicate target areas corresponding to wheel stops, curbs, ground locks, or other objects commonly associated with parking spaces. The systems may sample various points representing sensor returns to determine whether a target object is located in a target area, as well as to track the target object, in some instances.

### BACKGROUND

Effectively perceiving a surrounding environment is an essential element for various autonomous or semi-autonomous functionalities and tasks. In various instances, perception techniques may rely on a combination of sensors—such as cameras, LiDARs, RADARs, and/or ultrasonic sensors—to collect data from the environment. This data may then be processed using various perception algorithms and/or artificial intelligence (AI) techniques to classify objects, detect obstacles, perform localization, as well as potentially other operations so that an autonomous or semi-autonomous machine may navigate safely, make informed decisions, and avoid collisions. However, conventional systems may lack the ability to perceive certain obstacles in an environment. For instance, low-lying or near-ground obstacles can be challenging to detect and localize accurately since sensor returns for these obstacles are generally weaker than sensor returns for other objects.

### SUMMARY

Embodiments of the present disclosure relate to performing object perception using location-based knowledge for autonomous or semi-autonomous systems and applications. For instance, systems and methods described herein may more reliably perceive certain objects commonly found in predictable locations of an environment by leveraging known information related to the locations and/or the objects themselves. In some examples, the disclosed systems and methods may determine locations of target areas within a coordinate system associated with a target region in an environment, and use the target area locations to detect and track certain objects that may be otherwise difficult to perceive. As an example, a target region may be a parking space for a machine and the coordinate system may indicate target areas corresponding to wheel stops, curbs, ground locks, or other objects commonly associated with parking spaces. The systems may sample various points representing sensor returns to determine whether a target object is located in a target area. Once a target object is detected, the systems may track the target object while the machine performs various operations, as well as update the location, orientation, etc. of the detected target object is a more accurate detection is made (e.g., based on stronger sensor returns).

In contrast to conventional systems, the systems of the present disclosure, in some embodiments, are able to improve perception accuracy for certain obstacles that may be difficult to detect and/or localize using conventional techniques. For instance, by using geometric information associated with a parking space, the systems of the present disclosure may improve the perception accuracy for obstacles commonly associated with parking spaces (e.g., wheel stops, curbs, ground locks, etc.) and densely estimate the height of these obstacles. Additionally, in contrast to the conventional systems, the systems of the present disclosure, in some embodiments, then provide techniques for tracking and/or updating the locations of low-lying or other hard to detect obstacles. As such, and as described in more detail herein, by performing such processes, the systems of the present disclosure are able to better perform various operations associated with autonomous or semi-autonomous machines by using more accurate representations of the environment surrounding the machines. For instance, control components of the machines may make more informed decisions using perception data that indicates accurate locations of certain objects (e.g., low-lying objects) that may otherwise be difficult to localize or detect at all.

### BRIEF DESCRIPTION OF THE DRAWINGS

The present systems and methods for performing object perception using location-based knowledge for autonomous or semi-autonomous systems and applications are described in detail below with reference to the attached drawing figures, wherein:

FIG. 1 illustrates an example data flow diagram for a process of object perception using location-based knowledge, in accordance with some embodiments of the present disclosure;

FIG. 2 illustrates an example of an environment, in accordance with some embodiments of the present disclosure;

FIG. 3A illustrates examples of target regions that may be detected in the environment illustrated in FIG. 2, in accordance with some embodiments of the present disclosure;

FIG. 3B illustrates examples of target areas within a coordinate space associated with the target regions detected in the example of FIG. 3A, in accordance with some embodiments of the present disclosure;

FIG. 3C illustrates example sensor data returns corresponding to the target areas of the example of FIG. 3B, in accordance with some embodiments of the present disclosure;

FIGS. 3D-3F illustrate examples of lines that may be proposed between different points of the sensor data returns to determine a location or orientation of a target object disposed in the environment illustrated in the example of FIG. 2, in accordance with some embodiments of the present disclosure;

FIG. 4 is a data flow diagram illustrating an example associated with detecting one or more objects in a region of interest, in accordance with some embodiments of the present disclosure;

FIG. 5 illustrates an example of a system that may perform one or more of the processes described herein, in accordance with some embodiments of the present disclosure;

FIG. 6 is a flow diagram illustrating an example method for object perception using location-based knowledge, in accordance with some embodiments of the present disclosure;

FIG. 7 is a flow diagram illustrating an example method for detecting and tracking target objects disposed in target regions of an environment, in accordance with some embodiments of the present disclosure;

FIG. 8A is an illustration of an example autonomous vehicle, in accordance with some embodiments of the present disclosure;

FIG. 8B is an example of camera locations and fields of view for the example autonomous vehicle of FIG. 8A, in accordance with some embodiments of the present disclosure;

FIG. 8C is a block diagram of an example system architecture for the example autonomous vehicle of FIG. 8A, in accordance with some embodiments of the present disclosure;

FIG. 8D is a system diagram for communication between cloud-based server(s) and the example autonomous vehicle of FIG. 8A, in accordance with some embodiments of the present disclosure;

FIG. 9 is a block diagram of an example computing device suitable for use in implementing some embodiments of the present disclosure; and

FIG. 10 is a block diagram of an example data center suitable for use in implementing some embodiments of the present disclosure.

### DETAILED DESCRIPTION

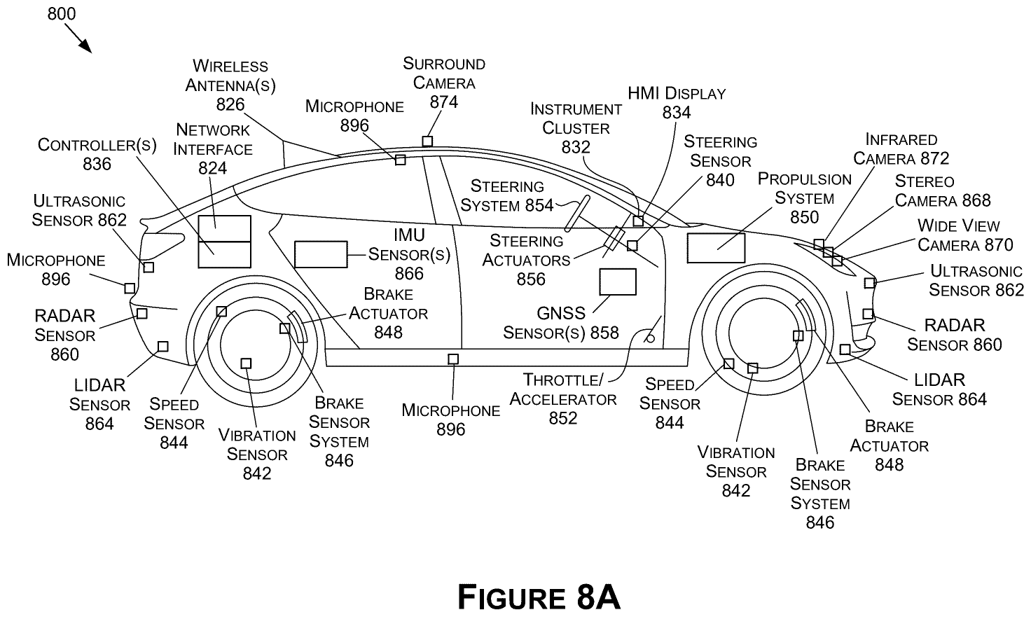

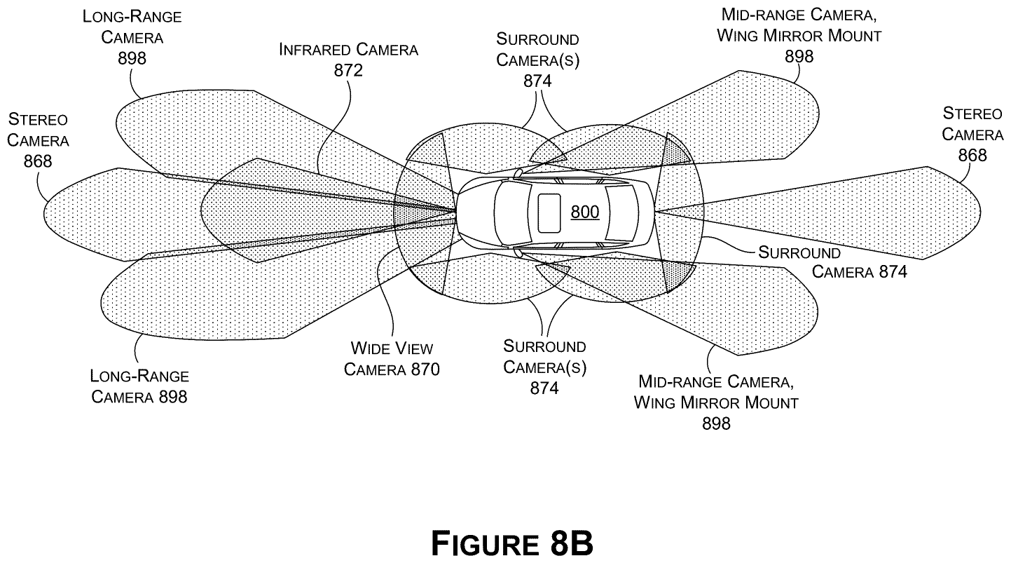

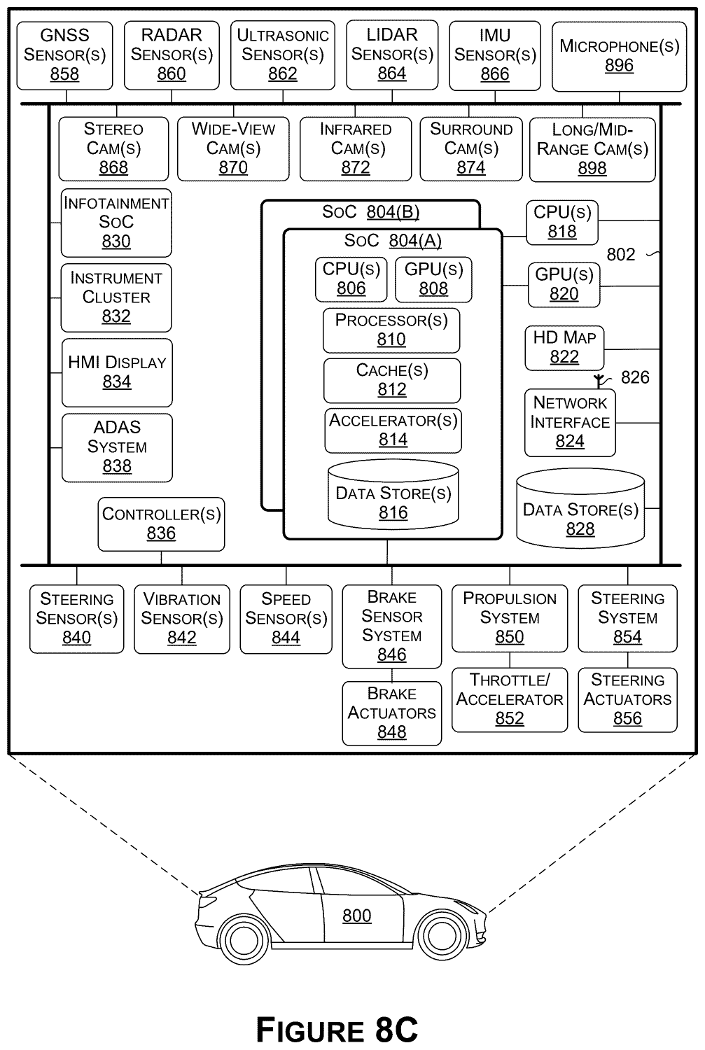

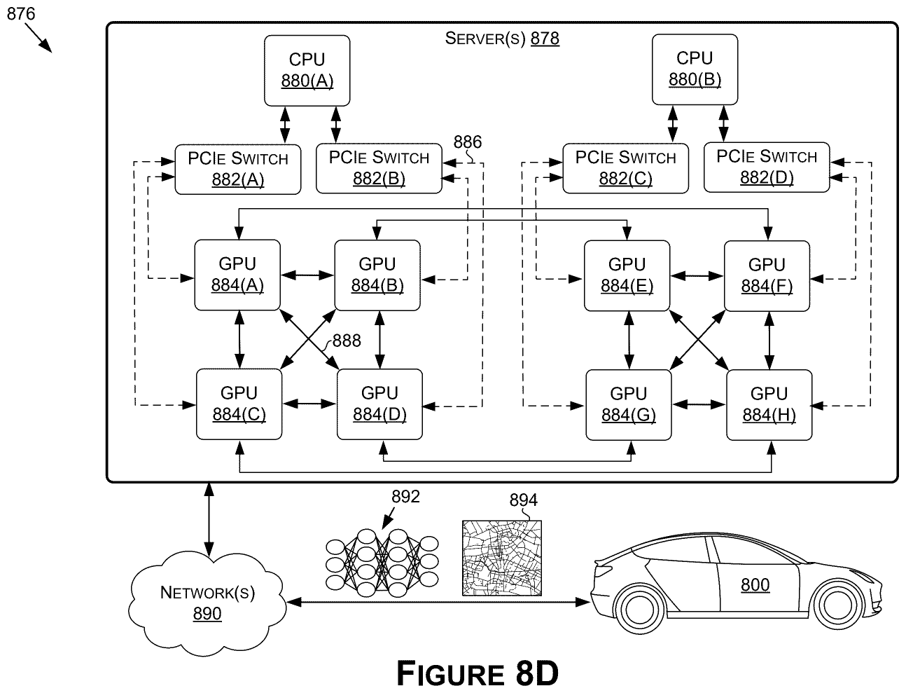

Systems and methods are disclosed related to performing object perception using location-based knowledge for autonomous or semi-autonomous systems and applications. Although the present disclosure may be described with respect to an example autonomous or semi-autonomous vehicle or machine 800 (alternatively referred to herein as “vehicle 800,” “ego-vehicle 800,” “ego-machine 800,” or “machine 800,” an example of which is described with respect to FIGS. 8A-8D), this is not intended to be limiting. For example, the systems and methods described herein may be used by, without limitation, non-autonomous vehicles or machines, semi-autonomous vehicles or machines (e.g., in one or more adaptive driver assistance systems (ADAS)), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, underwater craft, drones, and/or other vehicle types. In addition, although the present disclosure may be described with respect to detecting objects in parking spaces, this is not intended to be limiting, and the systems and methods described herein may be used in augmented reality, virtual reality, mixed reality, robotics, security and surveillance, autonomous or semi-autonomous machine applications, and/or any other technology spaces where object detection and/or map creation may be used.

By way of example, and not limitation, a system(s) may determine regions of interest in an environment surrounding a machine, and use the regions of interest to detect and track locations of objects (referred to herein as “target object”) in the environment. For instance, the system(s) may analyze perception data to determine a location of a region of interest, and then evaluate whether sensor returns corresponding to the region of interest are indicative of a presence of a target object being disposed at that location. If the target object is detected, the system(s) may update a map to indicate various attributes (e.g., location, size, orientation, etc.) of the target object. In some examples, the system(s) may track the location and/or other attributes of the target object in subsequent perception iterations. For instance, if the machine moves from one location to another location in the environment, the location of the target object may be tracked so that the position of the target object with respect to the machine or the environment may be determined even if sensor data returns for the target object are weak. Additionally, or alternatively, the system(s) may update the location or other attributes of the target object in subsequent iterations. For instance, if the sensor data returns become stronger for the target object, the system(s) may determine more accurate predictions and update the location/attributes.

In some examples, the regions of interest may correspond to a location(s) or an area(s) in the environment where a probability of a certain type(s) of object(s) being disposed at the location(s)/area(s) is greater than a threshold. That is, in some examples a region of interest may correspond to a location/area where a certain object or group of objects may likely be disposed. Additionally, in some examples, regions of interest may include one or more sub-regions of interest. For example, and as described herein, a parking space for a machine (e.g., vehicle) may be a region of interest (or “target region”) that includes one or more sub-regions of interest (or “target areas”). While the parking space may be associated with a first region of interest or target region in the environment, parking barriers and/or other objects commonly associated with parking spaces-such as wheel stops, curbs, ground locks, etc.—may be associated with second regions of interest or target areas within the first region of interest or target region, respectively.

In some instances, the system(s) may use various modalities of input data to determine the regions of interest and/or detect objects in the environment. For instance, the system(s) may generate and/or use various modalities of sensor data and/or map data to determine the presence of a region of interest in the environment and/or a presence of a target object in the region of interest. Additionally, or alternatively, the system(s) may use perception data that is generated based at least on the sensor data and/or the map data. The perception data may include a dense obstacle map (e.g., an evidence grid map (EGM)) representative of locations and other information associated with various obstacles in the environment. In some examples, the system(s) may use previous outputs to determine the regions of interest and/or detect the objects. For instance, as described above and herein, the system(s) may track the objects and/or regions of interest identified in the environment, and these tracks may be used as inputs for subsequent iterations. In at least one embodiment, the system may determine the presence of one or more first regions of interest within the environment, and the one or more first regions of interest may include one or more second regions of interest representative of one or more potential locations of one or more target objects. For example, the first region(s) of interest may correspond to a parking space(s) in the environment and the second region(s) of interest may correspond to a parking barrier(s) associated with the parking space(s), such as a wheel stop(s), a ground lock(s), a curb(s), or any other object(s).

In some examples, based at least on identifying the regions of interest in the environment, the system(s) may obtain or determine a subset of the input data that corresponds to the regions of interest. For instance, the system(s) may obtain or determine one or more portions of the sensor data (e.g., RADAR data), map data, perception data, or other input data that corresponds to the regions of interest. As an example, the system(s) may obtain input data that corresponds to an entire region of interest for an entire portion of a parking space. Additionally, or alternatively, the system(s) may obtain input data that corresponds to the sub-regions of interest within the parking space, such as input data corresponding to the regions of interest (e.g., a base, bottom, or end region) for the parking space objects (e.g., wheel stops, ground locks, curbs, etc.).

In some examples, the system(s) may vectorize the input data. For example, the system(s) may vectorize the dense obstacle map into arrays of points/pixels with associated information. In some examples, a point of the dense obstacle map may be vectorized into an array to indicate an x-coordinate location of the point, a y-coordinate location of the point, a z-coordinate location of the point (e.g., height), a boundary confidence score associated with the point, and/or any other features. In some examples, because the system(s) may be focused on detection of low-lying or near-ground objects such as parking space objects, the system(s) may use minimum and/or maximum height thresholds to further filter the number of points for evaluation within the regions of interest. For instance, the system(s) may use minimum/maximum height thresholds of 7 cm to 25 cm to filter out points/objects that are shorter or taller than the height thresholds. The system(s) may also use edge score thresholds and/or point uncertainty thresholds to vectorize the input data.

In various instances, the system(s) may detect or otherwise determine a presence of a target object in the region of interest. For instance, the system(s) may determine that a number of sensor returns/data points within the region of interest meets or exceeds a threshold. These sensor returns/data points may have coordinates (e.g., x, y, z coordinates) and/or edges that correspond to the target object type associated with the region of interest. For instance, the various coordinates of the sensor returns may correlate with the expected dimensions of the target object associated with the region of interest. In at least one embodiment, the target objects may be associated with vertical dimensions that are less than a threshold, and the system(s) may determine that the points correspond to the target objects based at least on vertical measurements associated with the points being less than the threshold vertical dimension. Additionally, or alternatively, a strong correlation of points within the region of interest may be indicative of the target object being disposed therein. In some examples, the system(s) may obtain map data indicating the locations of the regions of interest and evaluate the sensor data, perception data, and/or vectorized data with respect to the map data to determine the presence of the target objects and/or target regions.

In some examples, the system(s) may predict or otherwise determine the location and/or other attributes of the object in the region of interest. In at least one instance, the system(s) may determine the location and orientation (e.g., pose) of the target object by proposing one or more locations and/or orientations of the target object over one or more iterations, and selecting a best location/orientation based on a metric(s). For example, the system(s) may fit a line between two points (e.g., a first point and a second point) of the sensor data points/returns in the region of interest. The system(s) may then compute an alignment score associated with an alignment of the line with respect to one or more third points of the sensor data points/returns in the region of interest. If a value of the alignment score meets or exceeds a threshold (e.g., 60% alignment, 70% alignment, 80% alignment, etc.), the system(s) may register the line as the orientation/location of the target object. If the alignment score is less than the threshold, the system(s) may fit another line between two more points and re-attempt the process. This may be repeated across one or more subsequent iterations in which new sensor data is obtained and/or the machine has moved. In some examples, if the system(s) determines a new line in a subsequent iteration that has a greater alignment score than a previous line, the system(s) may replace the previous line with the new line and/or combine the lines. On the other hand, if the new line has a weaker alignment score or is less than the threshold, the system(s) may continue to use the previous line as the location/orientation of the target object.

In some instances, the system(s) may track the locations, orientations, and/or other attributes of the target objects detected in the regions of interest. For example, after determining that an alignment score associated with a predicted location of a target object meets or exceeds the threshold, the system(s) may register the location of the target object on an obstacle map and track the location of the object responsive to operations performed by the machine, such as the machine moving from one location to another location. As described herein, the target objects may be tracked in a number of ways. In the context of parking spaces, for example, if a target object was already detected the target object from a previous frame (e.g., of the obstacle map) may be populated to a current frame and/or merged with new detections by, e.g., a sum of 2 gaussians. If there was no previous detection or valid detection of the target object, the system(s) may add the new detection to the parking space region of interest. Additionally, in some examples, the system(s) may terminate or suppress certain target objects from the obstacle map.

In at least one example, the system(s) may generate one or more visualizations associated with the detected target object in the region of interest. For instance, the system(s) may rasterize a representation of the target object on the obstacle map. The obstacle map may depict or otherwise indicate locations of various objects in the environment. In some examples, the system(s) may generate the obstacle map based at least on the sensor data, perception data, or other data. The system(s) may sue the obstacle map for the tracking of the predicted locations of the target object.

As described herein, the system(s) may perform one or more operations associated with the machine based at least on the detection and tracking of the target objects in the regions of interest. For example, if the region of interest is the parking space and/or parking space objects, the system(s) may cause the machine to perform one or more operations associated with parking the machine in the parking space. That is, the system(s) may use the locations, orientations, and/or other attributes of the parking space objects associated with the parking space to localize the machine with respect to a coordinate system associated with the parking space. Additionally, or alternatively, the system(s) may use the locations, orientations, and/or other attributes of the parking space objects to localize the coordinate system associated with the parking space, and then perform operations to park the vehicle based on determining the parking space coordinate system. Such operations may include, in some examples, steering the machine, stopping the machine, accelerating the machine, reversing the machine, planning a path for the machine to follow, disengaging the machine, causing the machine to follow a trajectory, or any other operations.

In some embodiments, the systems and methods described herein may be performed within a simulation environment (e.g., NVIDIA's DriveSIM) using simulated data (e.g., simulated sensor data of simulated sensors of a virtual or simulated machine). For example, simulated sensor data and/or map data may be used to identify regions of interest (e.g., parking spaces) and sub-regions of interest (e.g., sub-regions of a parking space that includes a curb, wheel stop, etc.) within the simulation environment, and may use this information to perform operations (e.g., parking) associated with the virtual machine within the environment. These simulated operations may be used to test performance of the underlying algorithms, systems, and/or processes prior to deploying them in the real-world. In some instances, the simulation may be used to generate synthetic training data—e.g., training data including regions of interest and/or sub-regions of interest from within the simulation. The synthetic training data (in addition to or alternatively from real-world data) may then be processed to determine geometry and/or other information related to regions of interest, such as parking spaces or pallet delivery locations within a warehouse, for example. In any example, such as where a simulation environment is used for testing, validation, training, etc., the simulation environment and/or associated training data may be rendered or otherwise generated using one or more light transport algorithms-such as ray-tracing and/or path-tracing algorithms. In some embodiments, the simulation environment and/or one or more objects, features, or components thereof may be generated or managed within a three-dimensional (3D) content collaboration platform (e.g., NVIDIA's OMNIVERSE) for industrial digitalization, generative physical AI, and/or other use cases, applications, or services. For example, the content collaboration platform or system may include a system for using or developing universal scene descriptor (USD) (e.g., OpenUSD) data for managing objects, features, scenes, etc. within a simulated environment, digital environment, etc. The platform may include real physics simulation, such as using NVIDIA's PhysX SDK, in order to simulate real physics and physical interactions with simulations hosted by the platform. The platform may integrate OpenUSD along with ray tracing/path tracing/light transport simulation (e.g., NVIDIA's RTX rendering technologies) into software tools and simulation workflows for building, training, deploying, or testing AI systems-such as systems for testing, validating, training (e.g., machine learning models, neural networks, etc.), and/or other tasks related to automotive, robot, machine, or other applications.

The systems and methods described herein may be used by, without limitation, non-autonomous vehicles or machines, semi-autonomous vehicles or machines (e.g., in one or more adaptive driver assistance systems (ADAS)), autonomous vehicles or machines, piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, underwater craft, drones, and/or other vehicle types. Further, the systems and methods described herein may be used for a variety of purposes, by way of example and without limitation, for machine control, machine locomotion, machine driving, synthetic data generation, model training, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational AI, light transport simulation (e.g., ray-tracing, path tracing, etc.), collaborative content creation for 3D assets, cloud computing and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems for performing digital twin operations, systems implemented using an edge device, systems implementing language models, such as large language models (LLMs), vision language models (VLMs), and/or multi-modal language models, systems incorporating one or more virtual machines (VMs), systems for performing synthetic data generation operations, systems implemented at least partially in a data center, systems for performing conversational AI operations, systems for performing light transport simulation, systems for performing collaborative content creation for 3D assets (e.g., using USD, OpenUSD, ray-tracing/path tracing/light transport simulation, etc., such as NVIDIA's OMNIVERSE), systems for performing generative AI operations, systems implemented at least partially using cloud computing resources, and/or other types of systems.

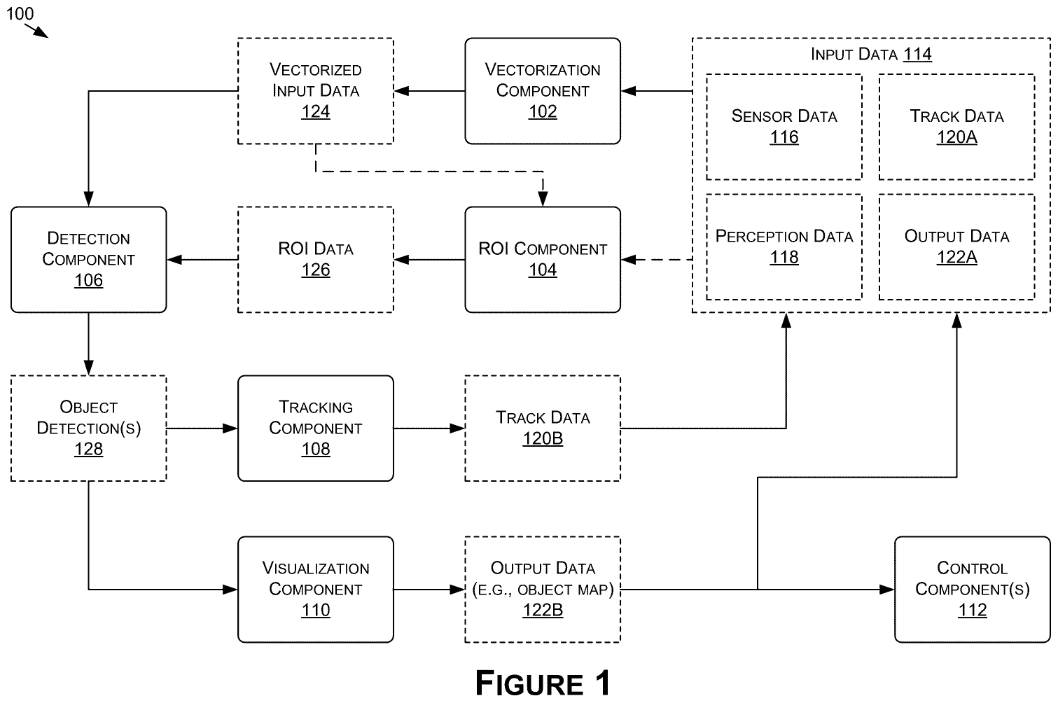

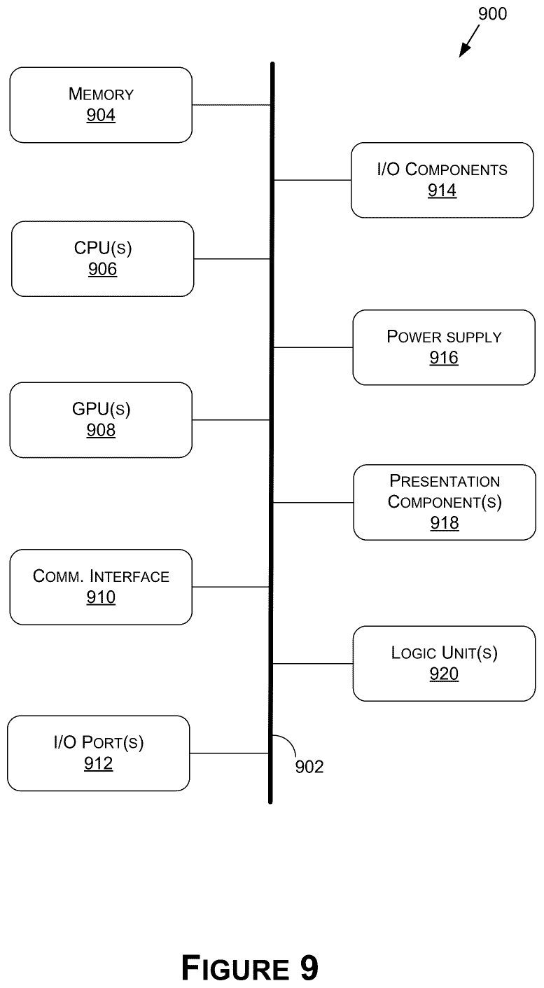

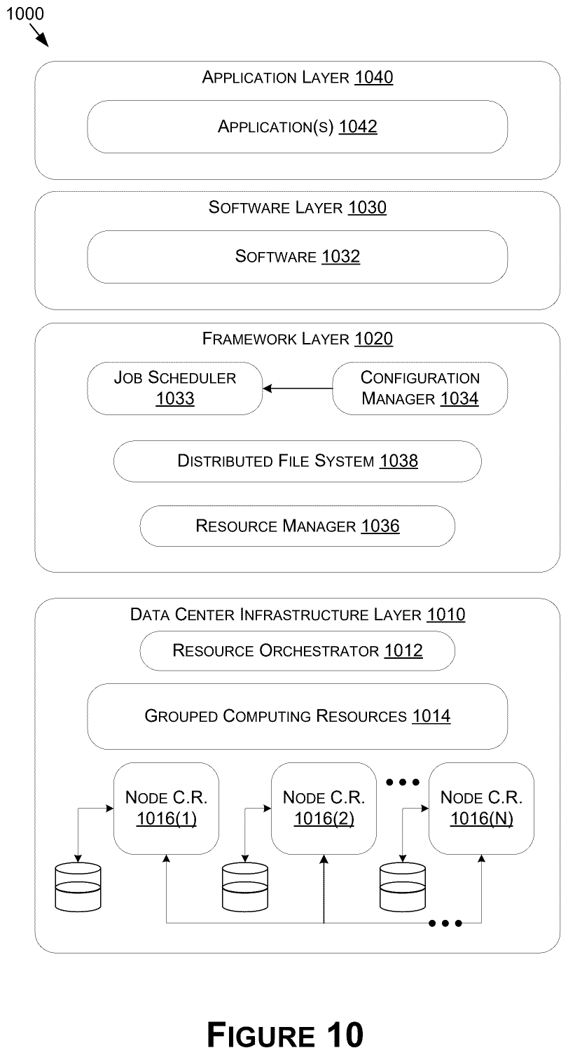

With reference to FIG. 1, FIG. 1 illustrates an example data flow diagram for a process 100 of object perception using location-based knowledge, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory. In some embodiments, the systems, methods, and processes described herein may be executed using similar components, features, and/or functionality to those of example autonomous vehicle 800 of FIGS. 8A-8D, example computing device 900 of FIG. 9, and/or example data center 1000 of FIG. 10.

The process 100 may be implemented using, amongst additional or alternative components, a vectorization component 102, a region of interest (ROI) component 104, a detection component 106, a tracking component 108, a visualization component 110, and one or more control components 112.

As an overview, the vectorization component 102 may be configured to receive input data 114, which may include sensor data 116, perception data 118, track data 120A, and output data 122A. The vectorization component may use some or all of the input data 114 to determine vectorized input data 124. Additionally, the ROI component 104 may be configured to receive at least some of the input data 114 and/or the vectorized input data 124 and determine one or more regions of interest in an environment, which may be represented using the ROI data 126. The detection component 106 may use the vectorized input data 124 and the ROI data 126 to determine one or more object detections 128. The tracking component 108 may receive the object detection(s) 128 and generate track data 120B representative of one or more tracked locations of the objects. Additionally, the visualization component 110 may receive the object detection(s) 128 and generate output data 122B, which may represent an object map. The control component(s) 112 may use the output data 122B to perform one or more control operations for a machine—such as the machine 800—in the environment.

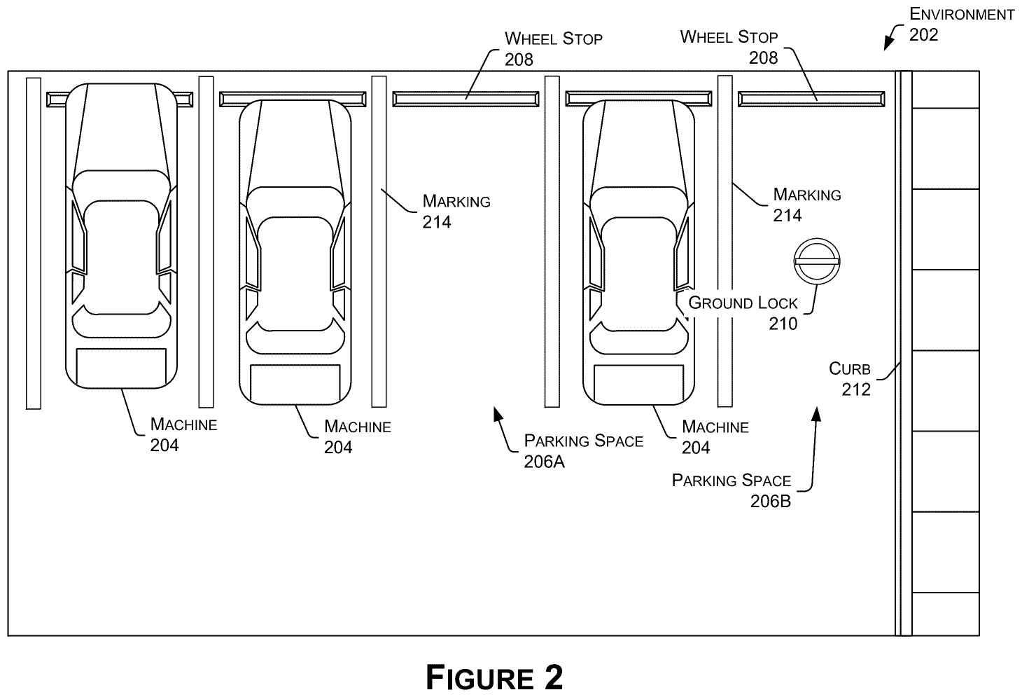

As described herein, the ROI component 104 may use the input data 114 and/or the vectorized input data 124 to determine regions of interest in an environment surrounding the machine, and the detection component 104 may leverage the regions of interest to determine locations, orientations, or any other attributes of objects in the environment. For instance, FIG. 2 illustrates an example of an environment 202, in accordance with some embodiments of the present disclosure. The environment 202 may include various objects, such as the machines 204 and/or other objects not shown, such as pedestrians, buildings, structures, trees, vegetation, animals, etc. The environment 202 illustrated in the example of FIG. 2 includes parking spaces 206A and 206B, which are designated areas in the environment for parking machines, which may be similar to or the same as the machines 204. The parking spaces 206A and 206B may include or be associated with various objects and/or features, such as the wheel stops 208, the ground lock 210, the curb 212, and the markings 214. In some examples, the wheel stops 208 may be positioned at the front of the parking spaces 206, and the markings 214 may mark the sides of the parking spaces 206. In some instances, the markings 214 may be replaced with physical object boundaries, such as the curb 212 which corresponds to a boundary of the parking space 206B. However, the parking spaces 206 in the example of FIG. 2 are just a couple of examples, and in other examples, the parking spaces may include different features or objects.

In some examples, the regions of interest described herein may correspond to a location(s) or an area(s) in the environment where a probability of a certain type(s) of object(s) being disposed at the location(s)/area(s) is greater than a threshold. That is, in some examples a region of interest may correspond to a location/area where a certain object or group of objects may likely be disposed. As an example, and still with reference to FIG. 2, a region of interest may correspond to the parking spaces 206A and 206B, as well as the occupied parking spaces illustrated in FIG. 2. Within parking spaces, objects such as the wheel stops 208, the ground lock 210, the curb 212, and/or other objects not shown may commonly be found. That is, in a real-world setting, parking spaces may be similar to and include similar objects as the parking spaces 206A and 206B, and the systems and methods of the present disclosure may leverage this information to more accurately detect and track the parking space objects, localize parking space coordinate systems, localize a machine with respect to the parking space, etc. As another example, the regions of interest may correspond to factory locations for parking robots, factory machines, etc. and/or for placing warehouse items. In such examples, the parking space objects may be parking space indicators or objects, or may include other objects (e.g., pallets, boxes, etc.) that may serve as indicators of an extent or geometry of an object placement location.

Additionally, in some examples, while a region of interest may correspond to a whole parking space for the purposes of the present disclosure, other regions of interest may also correspond to the parking space objects (e.g., the wheel stops 208, the ground lock 210, the curb 212, etc.). For example, and as described herein, the parking space 206B may be a region of interest (or “target region”) that includes one or more sub-regions of interest (or “target areas”). While the parking space 206B may be associated with a first region of interest or target region in the environment 202, the wheel stop 208, the ground lock 210, and the curb 212 may be associated with second regions of interest or target areas within the first region of interest or target region, respectively.

Referring back to the example of FIG. 1, the process 100 may include the vectorization component 102 generating the vectorized input data 124. For example, the vectorization component 102 may vectorize one or more portions of the input data 114 to generate the vectorized input data 124. That is, the vectorization component 102 may convert the input data 114 (or any one of the sensor data 116, the perception data 181, the track data 120A, and/or the output data 122A) into a structured format that can be handled by computational algorithms associated with the ROI component 104, the detection component 106, the tracking component 108, and/or the visualization component 110.

As one example, the sensor data 116 and/or the perception data 118 may be associated with various formats such as images, time-series readings, point clouds, etc. Vectorizing such data may involve the vectorization component 102 transforming these formats into numerical vectors. For instance, in the context of images, the vectorization component 102 may represent each pixel value as a component of a vector. For time-series data, the vectorization component 102 may represent each timestamped reading as a feature in a vector. For point clouds (e.g., RADAR point clouds, LiDAR point clouds, etc.), the vectorization component 102 may represent each point's coordinates as components in a vector.

In some examples, the vectorization component 102 and/or a preprocessing component (not shown) may perform one or more preprocessing steps, such as normalization (e.g., scaling data to a standard range), cleaning (e.g., removing outliers or irrelevant data), or any other preprocessing operations, to ensure the vectors represent meaningful and consistent information. Additionally, in some instances, the vectorization component 102 may extract one or more features, where relevant features (e.g., like edges in images, frequencies in signals, coordinates in points, etc.) are extracted to create meaningful vector representations that capture the essence of the input data 114. By vectorizing at least some of the input data 114 to generate the vectorized input data 124, the vectorization component 102 may improve computational efficiency of the technologies disclosed herein. For instance, the ROI component 104 and/or the detection component 106 may perform operations (e.g., matrix multiplications, distance calculations, alignment calculations, correlation calculations, etc.) more efficiently by using the vectorized input data 124 as compared to raw, unstructured data formats.

In some examples, the input data 114 may include a dense obstacle map, and the vectorization component 102 may vectorize the dense obstacle map into arrays of points/pixels with associated information. In some examples, the vectorization component 102 may vectorize a point of the dense obstacle map into an array of one or more vectors to indicate an x-coordinate location of the point, a y-coordinate location of the point, a z-coordinate location of the point (e.g., height), a boundary confidence score associated with the point, or any other features. In some examples, because the detection component 106 may be configured to detect low-lying or near-ground objects—such as parking space objects—the vectorization component 102 may use minimum and/or maximum height thresholds to further filter the number of points for evaluation within the regions of interest. For instance, the vectorization component 102 may use minimum/maximum height thresholds of 7 cm to 25 cm to filter out points/objects that are shorter or taller than the height thresholds. The height thresholds may correspond to the heights of the wheel stops 208, the ground locks 210, and/or the curb 212. The vectorization component 102 may also use edge score thresholds and/or point uncertainty thresholds to vectorize one or more portions of the input data 114.

The process 100 may also include the ROI component 104 using one or more modalities of the input data 114 and/or the vectorized input data 124 to generate the ROI data 126 representative of the regions of interest in the environment. For instance, the ROI component 104 may use various modalities of sensor data 116, map data (not shown), perception data 118, or other data to determine the presence of a region of interest in the environment. In some examples, the ROI component 104 may use previous outputs—such as outputs represented using the output data 122A, which may correspond to previous versions of the outputs 122B—to determine the regions of interest in the environment. In at least one embodiment, the ROI component 104 may determine the presence of one or more first regions of interest within the environment, and the one or more first regions of interest may include one or more second regions of interest representative of one or more potential locations of one or more target objects. For example, the first region(s) of interest may correspond to a parking space(s) in the environment and the second region(s) of interest may correspond to parking space objects associated with the parking space(s), such as a wheel stop(s), a ground lock(s), a curb(s), or any other object(s).

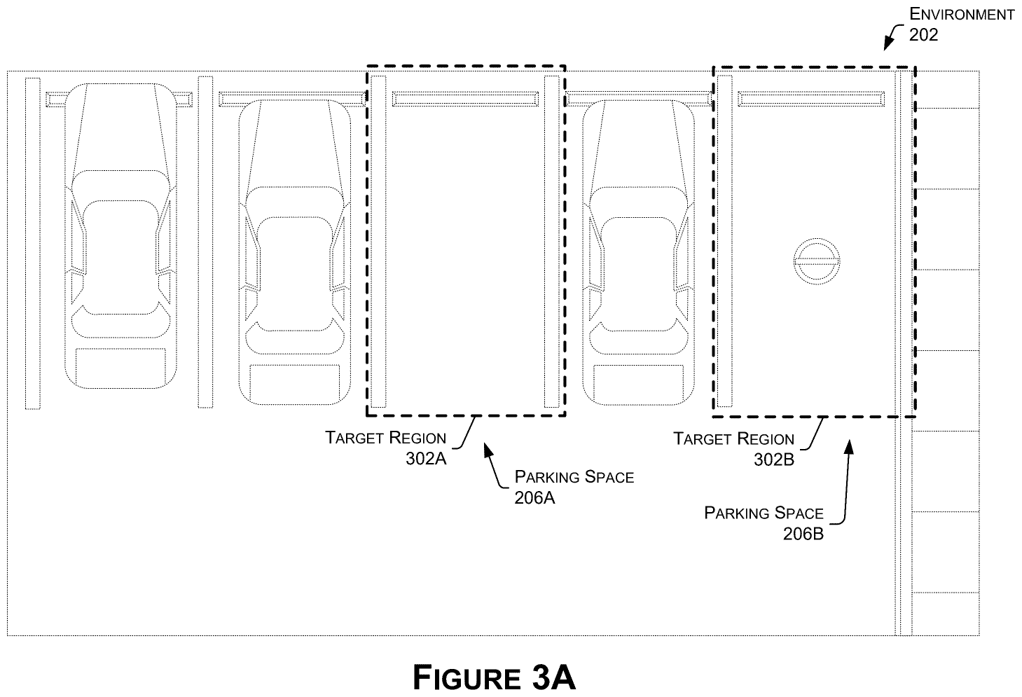

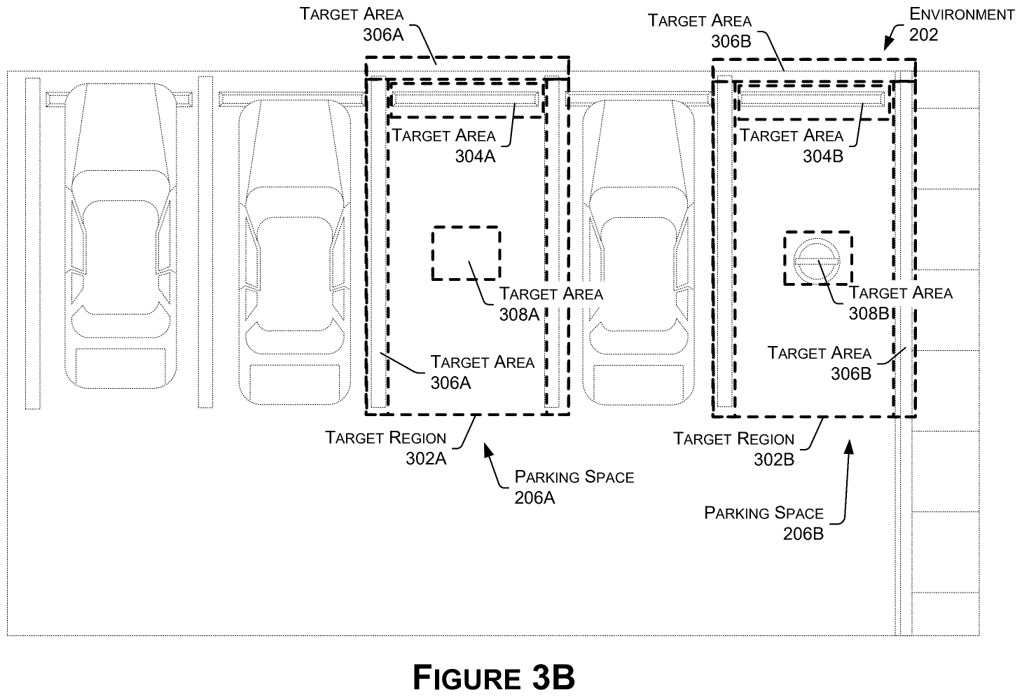

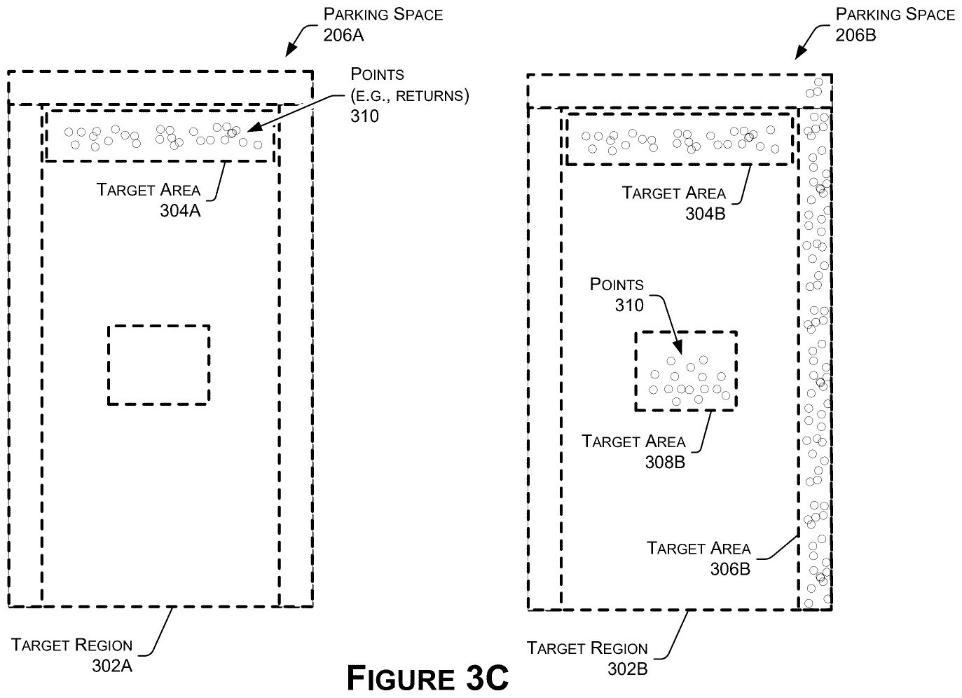

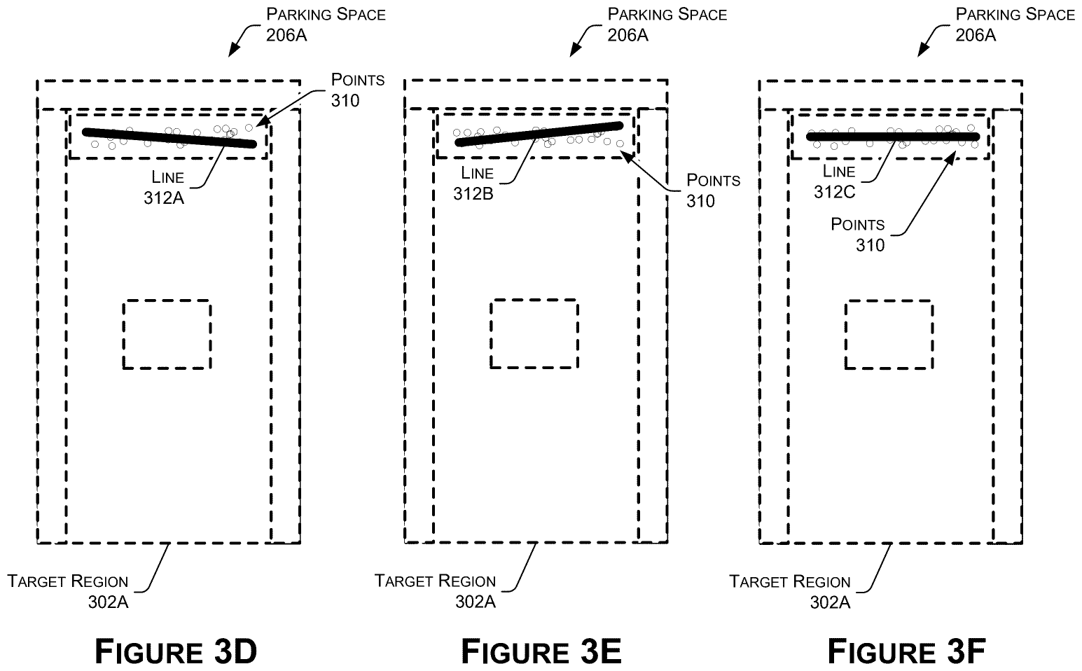

For instance, FIG. 3A illustrates examples of target regions (or “regions of interest”) that may be detected in the environment illustrated in FIG. 2, in accordance with some embodiments of the present disclosure. The target regions may include a first target region 302A corresponding to the first parking space 206A and a second target region 302B corresponding to the second parking space 206B. In some examples, the ROI component 104 may determine the target regions 302 based at least on the input data 114 and/or the vectorized input data 124. Referring now to FIG. 3B, FIG. 3B illustrates examples of target areas within a coordinate space associated with the target regions 302 detected in the example of FIG. 3A, in accordance with some embodiments of the present disclosure. The target areas may correspond to various locations in the target regions 302 where the target objects may commonly be found. For instance, the first target region 302A may be associated with a target area 304A corresponding to average wheel stop locations, target areas 306A corresponding to average curb locations, and a target area 308A corresponding to average ground lock locations. Similarly, the second target region 302B may be associated with a target area 304B corresponding to average wheel stop locations, target areas 306B corresponding to average curb locations, and a target area 308B corresponding to average ground lock locations. The target areas 304-308 may be positioned within the target regions 302 at locations corresponding to where those objects (e.g., the wheel stops, the curbs, or the ground locks) are usually located with respect to a parking space.

Referring back to the example of FIG. 1, the process 100 may also include the detection component 106 obtaining or determine a subset of the vectorized input data 124 that corresponds to the regions of interest indicated in the ROI data 126. For instance, the detection component 106 may obtain or determine one or more portions of the vectorized input data 124 that corresponds to the regions of interest. As an example, the detection component 106 may obtain the vectorized input data 124 that corresponds to an entire parking space. Additionally, or alternatively, the detection component 106 may obtain the vectorized input data 124 that corresponds to the sub-regions of interest within the parking space, such as the vectorized input data 124 corresponding to the regions of interest for the parking space objects (e.g., wheel stops, ground locks, curbs, etc.).

In various instances, the detection component 106 may detect or otherwise determine a presence of a target object in the region of interest. For instance, the detection component 106 may determine that a number of sensor returns/data points within the region of interest meets or exceeds a threshold. These sensor returns/data points may have coordinates (e.g., x, y, z coordinates) and/or edges that correspond to the target object type associated with the region of interest. For instance, the various coordinates of the sensor returns may correlate with the expected dimensions of the target object associated with the region of interest. In at least one embodiment, the target objects may be associated with vertical dimensions that are less than a threshold, and the detection component 106 may determine that the points correspond to the target objects based at least on vertical measurements associated with the points being less than the threshold vertical dimension. Additionally, or alternatively, a strong correlation of points within the region of interest may be indicative of the target object being disposed therein.

For example, FIG. 3C illustrates example points representing sensor data returns corresponding to the target areas of the example of FIG. 3B, in accordance with some embodiments of the present disclosure. As illustrated in the example of FIG. 3C, a number of points 310 representing sensor returns may be located within the target areas of the target regions. For instance, a first number of points 310 are located within the target area 304A of the first target region 302A, a second number of points 310 are located within the target area 304B of the second target region 302B, a third number of points 310 are located within the target area 306B, and a fourth number of points 310 are located within the target area 308B of the target region 302B. In some examples, points in the target area 304A may correspond to sensor measurements associated with the wheel stop 208 of the parking space 206A, the points in the target area 304B may correspond to sensor measurements associated with the wheel stop 208 of the parking space 206B, the points in the target area 306B may correspond to sensor measurements associated with the curb 212, and the points in the target area 308B may correspond to sensor measurements associated with the ground lock 210.

In some examples, the detection component 106 may predict or otherwise determine the locations and/or other attributes of the target objects in the regions of interest. In at least one instance, the detection component 106 may determine the location and orientation (e.g., pose) of a target object by proposing one or more locations and/or orientations of the target object over one or more iterations, and selecting a best location/orientation based on a metric(s). For example, the detection component 106 may fit a line between two points (e.g., a first point and a second point) of the points 310 in the target areas. The detection component 106 may then compute an alignment score associated with an alignment of the line with respect to one or more third points of the sensor data points/returns. If the alignment score meets or exceeds a threshold, the detection component 106 may register the line as the orientation/location of the target object. If the alignment score is less than the threshold, the detection component 106 may fit another line between two more points and re-attempt the process. This may be repeated across one or more subsequent iterations in which new sensor data is obtained and/or the machine has moved. In some examples, if the detection component 106 determines a new line in a subsequent iteration that has a greater alignment score than a previous line, the detection component 106 may replace the previous line with the new line and/or combine the lines. On the other hand, if the new line has a weaker alignment score or is less than the threshold, the detection component 106 may continue to use the previous line as the location/orientation of the target object.

For instance, FIGS. 3D-3F illustrate examples of lines that may be proposed between different points of the sensor data returns to determine a location or orientation of a target object disposed in the environment illustrated in the example of FIG. 2, in accordance with some embodiments of the present disclosure. In FIG. 3D, the detection component 106 may propose a first line 312A between a first point and a second point of the points 310. The detection component 106 may then compute an alignment score for the first line 312A. The alignment score may indicate that an alignment of the first line 312A with respect to the collective group of the points 310 is less than a threshold, and the detection component 106 may propose a second line 312B, as illustrated in FIG. 3E. Similarly, with reference to FIG. 3E, the detection component 106 may propose the second line 312B between a third point and a fourth of the points 310. The detection component 106 may then compute an alignment score for the second line 312B. The alignment score may indicate that an alignment of the second line 312B with respect to the collective group of the points 310 is less than the threshold, and the detection component 106 may propose a third line 312C, as illustrated in FIG. 3F. With reference to FIG. 3F, the detection component 106 may propose the third line 312C between a fifth point and a sixth of the points 310. The detection component 106 may then compute an alignment score for the third line 312C. The alignment score may indicate that an alignment of the third line 312C with respect to the collective group of the points 310 meets or exceeds the threshold, and the detection component 106 may register the third line 312C as the correct predicted location/orientation of the wheel stop 208 of the parking space 206A.

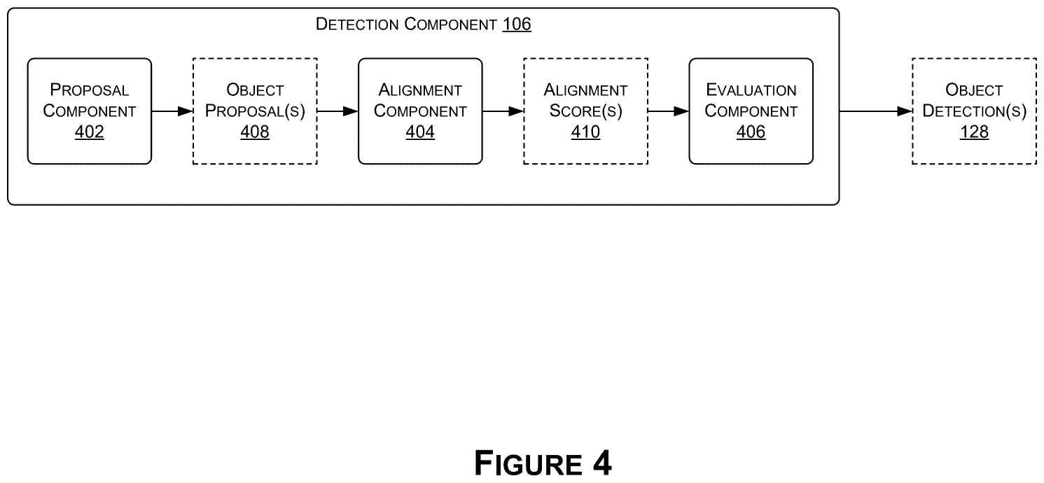

In some examples, the detection component 106 may include various components for proposing object locations, computing alignment scores, and determining/registering the locations/orientations of objects. For instance, FIG. 4 is a data flow diagram illustrating an example associated with detecting one or more objects in a region of interest, in accordance with some embodiments of the present disclosure. As illustrated in the example of FIG. 4, the detection component 106 may, in some examples, include a proposal component 402, an alignment component 404, and an evaluation component 406. The proposal component 402 may generate data corresponding to one or more object proposals 408. For instance, with reference to the examples of FIGS. 3D-3F, the proposal component 402 may propose the lines 312 between two points of the points 310 to estimate the orientation and/or location of the target object corresponding to the points 310. The alignment component 404 may use the object proposal(s) 408 to compute one or more alignment scores 410 for the object proposal(s) 408. That is, the alignment component 404 may compute one or more metrics indicating whether the lines 312A-312C determined by the proposal component are aligned with the group of points 310 as a whole. For instance, the alignment score(s) 410 for the lines 312A and 312B may be relatively low, whereas the alignment score 410 for the line 312C may be relatively high, indicating a strong alignment of the line 312C with the points 310. The evaluation component 406 may evaluate the alignment score(s) 410 to determine whether the object proposal(s) 408 are accurate for the target objects. That is, the evaluation component 406 may determine, based on the alignment score(s) 410, whether the predicted location and/or orientation of the target object is accurate with respect to the correlation of the points 310. Based on the evaluation of the alignment score(s) 410 by the evaluation component 406, the detection component 106 may output the object detection(s) 128.

In some examples, the detection component 106 may implement one or more algorithms to detect the locations and/or orientations of the target objects in the regions of interest. For instance, the detection component 106 may implement a Random Sample Consensus (RANSAC) algorithm to fit the lines and predict the locations of the target objects in the regions of interest. The detection component 106 may use such algorithms to sample the data points and determine the best location/orientation of the target object even in the presence of weak sensor data returns.

Referring back to the example of FIG. 1, the tracking component 108 may track the locations, orientations, and/or other attributes of the target objects detected in the regions of interest. For example, the tracking component 108 may obtain the object detection(s) 128 from the detection component 106 and generate track data 120B for each of the detected objects. In some examples, the tracking component 108 may track the location or orientation of the detected objects responsive to operations performed by the machine, such as the machine moving from one location to another location. As described herein, the tracking component 108 may track the objects in a number of ways. In the context of parking spaces, for example, if a target object was already detected by the detection component 106, the tracking component 108 may use the location of the target object from a previous frame (e.g., of the obstacle map) and populate the location to a current frame. If there was no previous detection or valid detection of the target object, the tracking component 108 may add the new detection to the parking space region of interest. Additionally, in some examples, the tracking component 108 may terminate or suppress certain target objects from the obstacle map, determine to stop tracking certain objects (e.g., based on moving far away from the objects), etc.

In at least one example, the visualization component 110 may generate one or more visualizations associated with the detected target object in the region of interest, and these visualizations may be represented by the output data 122B. For instance, the visualization component 110 may rasterize a representation of the target object on the obstacle map. The obstacle map may depict or otherwise indicate locations of various objects in the environment. In some examples, the visualization component 110 may generate the obstacle map based at least on the sensor data 116, the perception data 118, or other data, and then update the obstacle map using the object detection(s) 128.

The process 100 may also include the control component(s) 112 receiving the output data 122B. The control component(s) 112 may cause a machine, such as the machine 800, to perform one or more operations based at least on the output data 122B. For example, if the region of interest is the parking space and/or parking space objects, the control component(s) 112 may cause the machine to perform one or more operations associated with parking in the parking space. That is, the control component(s) 112 may use the locations, orientations, and/or other attributes of the parking space objects associated with the parking space to localize the machine with respect to a coordinate system associated with the parking space. Additionally, or alternatively, the visualization component 110 may use the locations, orientations, and/or other attributes of the parking space objects to localize the coordinate system associated with the parking space, and then the control component(s) 112 may perform operations to park the vehicle based on the parking space coordinate system.

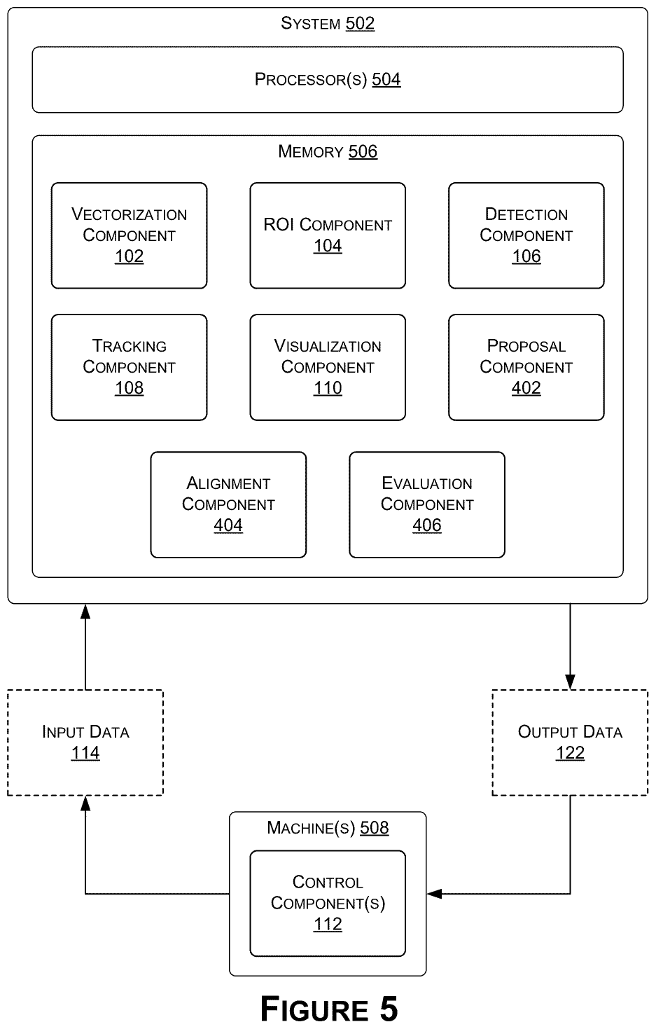

FIG. 5 illustrates an example of a system 502 that may perform one or more of the processes described herein, in accordance with some embodiments of the present disclosure. As shown, the system 502 (which may represent, and/or include, the example computing device(s) 900 and/or the example data center 1000) may include one or more processors 504 (which may be similar to, and/or include, the CPUs 906 and/or the GPUs 908) and memory 506 (which may be similar to, and/or include, the memory 904). For instance, the memory 506 may store the vectorization component 102, the ROI component 104, the detection component 106, the tracking component 108, the visualization component 110, the proposal component 402, the alignment component 404, and/or the evaluation component 406. Additionally, the processor(s) 504 may execute the vectorization component 102, the ROI component 104, the detection component 106, the tracking component 108, the visualization component 110, the proposal component 402, the alignment component 404, and/or the evaluation component 406 to perform one or more of the processes described herein.

Additionally, as shown by the example of FIG. 5, the system 502 may obtain input data 114 from one or more machines 508 (which may correspond to the machine 800). The input data 114 may correspond to sensor data (e.g., LiDAR data, RADAR data, ultrasonic data, image data, etc.) generate using one or more sensors (e.g., LiDAR sensors, RADAR sensors, ultrasonic sensors, cameras, etc.) of the machine(s) 508. Additionally, or alternatively, the input data 114 may include perception data generated using a perception system of the machine(s) 508, previous outputs of the system 502 (e.g., the output data 122), or any other kinds of input data. The system 502 may use the various components stored in the memory 506 to process the input data 114 and generate the output data 122. The output data 122 may represent one or more predicted locations associated with target objects located within one or more regions of interest. For example, the output data 122 may represent locations of parking space objects (e.g., wheel stops, curbs, ground locks, etc. associated with a parking space. The control component(s) 112 may then use the output data 122 to control the machine(s) 508 to perform one or more operations.

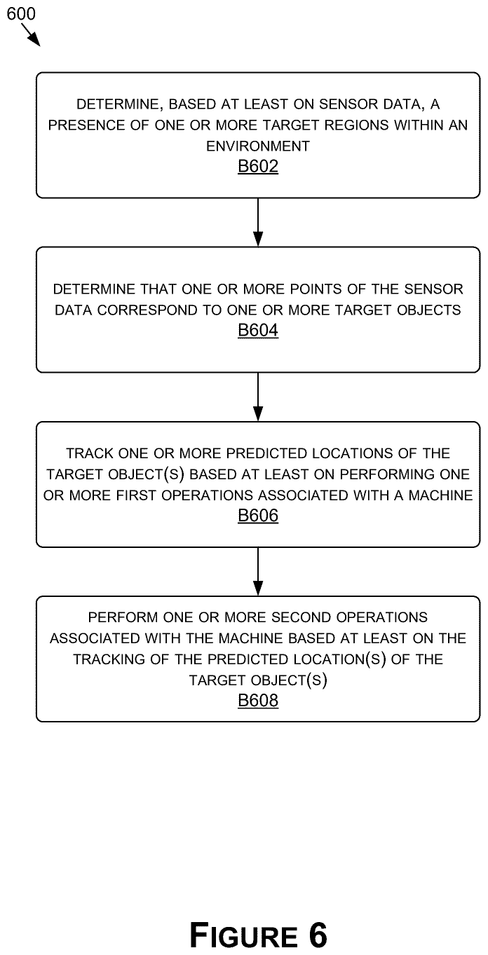

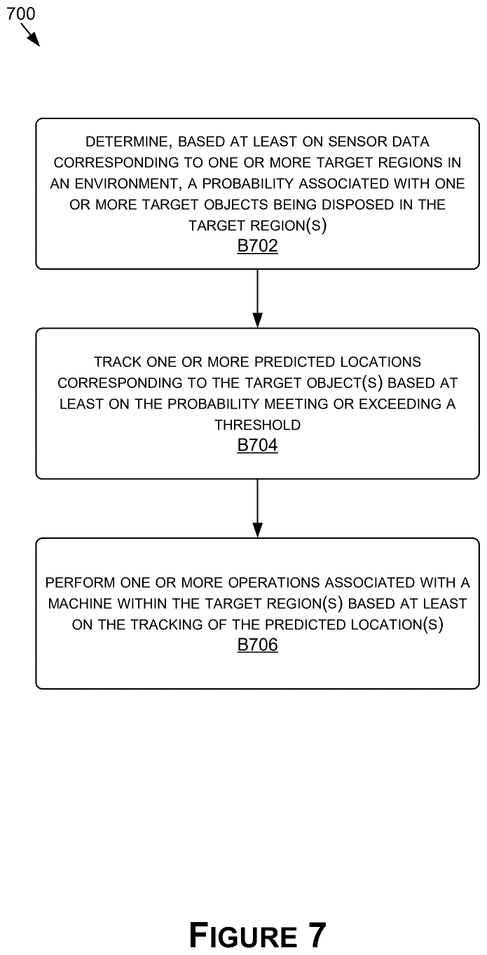

Now referring to FIGS. 6 and 7, each block of methods 600 and 700, described herein, comprises a computing process that may be performed using any combination of hardware, firmware, and/or software. For instance, various functions may be carried out by a processor executing instructions stored in memory. The methods may also be embodied as computer-usable instructions stored on computer storage media. The methods may be provided by a standalone application, a service or hosted service (standalone or in combination with another hosted service), or a plug-in to another product, to name a few. In addition, methods 600 and 700 are described, by way of example, with respect to FIG. 1. However, these methods may additionally or alternatively be executed by any one system, or any combination of systems, including, but not limited to, those described herein.

FIG. 6 is a flow diagram illustrating an example method for object perception using location-based knowledge, in accordance with some embodiments of the present disclosure. The method 600, at block B602, may include determining, based at least on sensor data, a presence of one or more target regions within an environment. For instance, the ROI component 104 may determine the presence of the target region(s) in the environment based at least on the sensor data 116. As described herein, the target region(s) may include one or more target areas representative of one or more potential locations of one or more target objects. As an example, the target region(s) may correspond to parking spaces, the target areas may correspond to likely locations of parking space objects (e.g., wheel stops, ground locks, curbs, etc.), and the target object(s) may correspond to the parking space objects.

The method 600, at block B604, may include determining that one or more points of the sensor data correspond to one or more target objects. For instance, the detection component 106 may determine that the point(s) of the sensor data 116 correspond to the target object(s). In some examples, the detection component 106 may use the ROI data 126 and the vectorized input data to determine a presence of the target object(s) in the environment. As described herein, the detection component 106 may determine the point(s) of the sensor data 116 correspond to the target object(s) based at least on a correlation of the point(s) within the target area(s) and/or based at least on a number of the points meeting or exceeding a threshold. Additionally, if one or more coordinates associated with the points are similar to one or more coordinates associated with the target objects, the detection component 106 may determine the points correspond to the target objects. That is, if the coordinates associated with the points correlate with sizes associated with the target objects, the points may correspond to the target objects.

In some examples, the detection component 106 may determine the location and orientation (e.g., pose) of a target object by proposing one or more locations and/or orientations of the target object over one or more iterations, and selecting the best location/orientation based on one or more metrics. For example, the detection component 106 may fit a line between two points (e.g., a first point and a second point) of the points in the target areas. The detection component 106 may then compute an alignment score associated with an alignment of the line with respect to the rest of the points in the target area. If the alignment score meets or exceeds a threshold, the detection component 106 may register the line as the orientation/location of the target object. If the alignment score is less than the threshold, the detection component 106 may fit another line between two more different points and re-attempt the process. This may be repeated across one or more subsequent iterations in which new sensor data is obtained and/or the machine has moved. In some examples, if the detection component 106 determines a new line in a subsequent iteration that has a greater alignment score than a previous line, the detection component 106 may replace the previous line with the new line and/or combine the lines. On the other hand, if the new line has a weaker alignment score or is less than the threshold, the detection component 106 may continue to use the previous line as the location/orientation of the target object.

The method 600, at block B606, may include tracking one or more predicted locations of the target object(s) based at least on performing one or more first operations associated with a machine. For instance, the tracking component 108 may track the predicted location(s) of the target object(s) responsive to the performing of the first operation(s) associated with the machine. In some examples, the first operation(s) may include the machine moving from one location to another location. For instance, the target object(s) may be a static object, and although the static object may remain in the same location, the machine may not. As the machine moves, the sensor returns for the static object may become weaker and the detection component 106 may be unable to accurately predict the location of the static object. As such, the tracking component 108 may track the target object's location so that the machine may perform operations with awareness of where the target object is located.

The method 600, at block B608, may include performing one or more second operations associated with the machine based at least on the tracking of the predicted location(s) of the target object(s). For instance, the control component(s) 112 may perform the second operation(s) associated with the machine based at least on the tracking component 108 tracking the predicted location(s) of the target object(s). That is, as explained above, as the machine moves (e.g., the first operation(s)), the sensor returns for the target object(s) may become weaker and the detection component 106 may be unable to accurately predict the location(s) of the target object(s). As such, the tracking component 108 may track the target object location(s) so that the control component(s) 112 may cause the machine to perform the second operation(s) with awareness of where the target object(s) is located.

FIG. 7 is a flow diagram illustrating an example method for detecting and tracking target objects disposed in target regions of an environment, in accordance with some embodiments of the present disclosure. The method 700, at block B702, may include determining, based at least on sensor data corresponding to one or more target regions in an environment, a probability associated with one or more target objects being disposed in the target region(s). For instance, the detection component 106 may determine based at least on the sensor data 116 corresponding to the target regions in the environment, the probability associated with the target object(s) being disposed in the target region(s). In some examples, the detection component 106 may determine the probability based at least on a number of sensor data points/measurements corresponding to one or more target spaces in the target region(s). For instance, the target region(s) may correspond to a parking space, the target space(s) may correspond to a likely location(s) of a parking space object(s), and the target object(s) may correspond to the parking space object(s).

The method 700, at block B704, may include tracking one or more predicted locations corresponding to the target object(s) based at least on the probability meeting or exceeding a threshold. For instance, based at least on the probability meeting or exceeding the threshold, the detection component 106 may determine the predicted location(s) of the target object(s) in the environment, and the tracking component 108 may track the predicted location(s) of the target object(s). Additionally, in some examples, the visualization component 110 may update an obstacle map with a representation of the target object(s) at the predicted location(s), and the tracking component 108 may use the obstacle map to track the predicted location(s) of the target object(s) responsive to one or more operations performed by a machine. For instance, if the machine moves from a first location to a second location, the tracking component 108 may keep track of the predicted location(s) of the target object(s) relative to the machine.

The method 700, at block B706, may include performing one or more operations associated with a machine within the target region(s) based at least on the tracking of the predicted location(s). For instance, the control component(s) 112 may cause or control performance of the operation(s) associated with the machine within the target region(s), and the control component(s) 112 may use the tracked, predicted location(s) of the target object(s) when causing or controlling the performance of the operation(s). In some examples, the operation(s) associated with the machine may be performed subsequent to the determination of the predicted location(s) and/or the tracking of the predicted location(s). For instance, the predicted location(s) of the target object(s) may be determined at a first time using first input data. Then, the machines may perform one or more operations and sensor data may no longer indicate a strong presence of the target object(s). Thus, at a second time after the first time, the sensor data may no longer indicate where the target object(s) is located, but based on the tracking of the predicted location(s), the control component(s) 112 may still have knowledge of where the target object(s) is most likely located and control the performance of the operation(s) accordingly.

### Example Autonomous Vehicle

FIG. 8A is an illustration of an example autonomous vehicle 800, in accordance with some embodiments of the present disclosure. The autonomous vehicle 800 (alternatively referred to herein as the “vehicle 800”) may include, without limitation, a passenger vehicle, such as a car, a truck, a bus, a first responder vehicle, a shuttle, an electric or motorized bicycle, a motorcycle, a fire truck, a police vehicle, an ambulance, a boat, a construction vehicle, an underwater craft, a robotic vehicle, a drone, an airplane, a vehicle coupled to a trailer (e.g., a semi-tractor-trailer truck used for hauling cargo), and/or another type of vehicle (e.g., that is unmanned and/or that accommodates one or more passengers). Autonomous vehicles are generally described in terms of automation levels, defined by the National Highway Traffic Safety Administration (NHTSA), a division of the US Department of Transportation, and the Society of Automotive Engineers (SAE) “Taxonomy and Definitions for Terms Related to Driving Automation Systems for On-Road Motor Vehicles” (Standard No. J3016-201806, published on Jun. 15, 2018, Standard No. J3016-201609, published on Sep. 30, 2016, and previous and future versions of this standard). The vehicle 800 may be capable of functionality in accordance with one or more of Level 3-Level 5 of the autonomous driving levels. The vehicle 800 may be capable of functionality in accordance with one or more of Level 1-Level 5 of the autonomous driving levels. For example, the vehicle 800 may be capable of driver assistance (Level 1), partial automation (Level 2), conditional automation (Level 3), high automation (Level 4), and/or full automation (Level 5), depending on the embodiment. The term “autonomous,” as used herein, may include any and/or all types of autonomy for the vehicle 800 or other machine, such as being fully autonomous, being highly autonomous, being conditionally autonomous, being partially autonomous, providing assistive autonomy, being semi-autonomous, being primarily autonomous, or other designation.

The vehicle 800 may include components such as a chassis, a vehicle body, wheels (e.g., 2, 4, 6, 8, 18, etc.), tires, axles, and other components of a vehicle. The vehicle 800 may include a propulsion system 850, such as an internal combustion engine, hybrid electric power plant, an all-electric engine, and/or another propulsion system type. The propulsion system 850 may be connected to a drive train of the vehicle 800, which may include a transmission, to enable the propulsion of the vehicle 800. The propulsion system 850 may be controlled in response to receiving signals from the throttle/accelerator 852.

A steering system 854, which may include a steering wheel, may be used to steer the vehicle 800 (e.g., along a desired path or route) when the propulsion system 850 is operating (e.g., when the vehicle is in motion). The steering system 854 may receive signals from a steering actuator 856. The steering wheel may be optional for full automation (Level 5) functionality.

The brake sensor system 846 may be used to operate the vehicle brakes in response to receiving signals from the brake actuators 848 and/or brake sensors.

Controller(s) 836, which may include one or more system on chips (SoCs) 804 (FIG. 8C) and/or GPU(s), may provide signals (e.g., representative of commands) to one or more components and/or systems of the vehicle 800. For example, the controller(s) may send signals to operate the vehicle brakes via one or more brake actuators 848, to operate the steering system 854 via one or more steering actuators 856, to operate the propulsion system 850 via one or more throttle/accelerators 852. The controller(s) 836 may include one or more onboard (e.g., integrated) computing devices (e.g., supercomputers) that process sensor signals, and output operation commands (e.g., signals representing commands) to enable autonomous driving and/or to assist a human driver in driving the vehicle 800. The controller(s) 836 may include a first controller 836 for autonomous driving functions, a second controller 836 for functional safety functions, a third controller 836 for artificial intelligence functionality (e.g., computer vision), a fourth controller 836 for infotainment functionality, a fifth controller 836 for redundancy in emergency conditions, and/or other controllers. In some examples, a single controller 836 may handle two or more of the above functionalities, two or more controllers 836 may handle a single functionality, and/or any combination thereof.

The controller(s) 836 may provide the signals for controlling one or more components and/or systems of the vehicle 800 in response to sensor data received from one or more sensors (e.g., sensor inputs). The sensor data may be received from, for example and without limitation, global navigation satellite systems (“GNSS”) sensor(s) 858 (e.g., Global Positioning System sensor(s)), RADAR sensor(s) 860, ultrasonic sensor(s) 862, LIDAR sensor(s) 864, inertial measurement unit (IMU) sensor(s) 866 (e.g., accelerometer(s), gyroscope(s), magnetic compass(es), magnetometer(s), etc.), microphone(s) 896, stereo camera(s) 868, wide-view camera(s) 870 (e.g., fisheye cameras), infrared camera(s) 872, surround camera(s) 874 (e.g., 360 degree cameras), long-range and/or mid-range camera(s) 898, speed sensor(s) 844 (e.g., for measuring the speed of the vehicle 800), vibration sensor(s) 842, steering sensor(s) 840, brake sensor(s) (e.g., as part of the brake sensor system 846), and/or other sensor types.

One or more of the controller(s) 836 may receive inputs (e.g., represented by input data) from an instrument cluster 832 of the vehicle 800 and provide outputs (e.g., represented by output data, display data, etc.) via a human-machine interface (HMI) display 834, an audible annunciator, a loudspeaker, and/or via other components of the vehicle 800. The outputs may include information such as vehicle velocity, speed, time, map data (e.g., the High Definition (“HD”) map 822 of FIG. 8C), location data (e.g., the vehicle's 800 location, such as on a map), direction, location of other vehicles (e.g., an occupancy grid), information about objects and status of objects as perceived by the controller(s) 836, etc. For example, the HMI display 834 may display information about the presence of one or more objects (e.g., a street sign, caution sign, traffic light changing, etc.), and/or information about driving maneuvers the vehicle has made, is making, or will make (e.g., changing lanes now, taking exit 34B in two miles, etc.).

The vehicle 800 further includes a network interface 824 which may use one or more wireless antenna(s) 826 and/or modem(s) to communicate over one or more networks. For example, the network interface 824 may be capable of communication over Long-Term Evolution (“LTE”), Wideband Code Division Multiple Access (“WCDMA”), Universal Mobile Telecommunications System (“UMTS”), Global System for Mobile communication (“GSM”), IMT-CDMA Multi-Carrier (“CDMA2000”), etc. The wireless antenna(s) 826 may also enable communication between objects in the environment (e.g., vehicles, mobile devices, etc.), using local area network(s), such as Bluetooth, Bluetooth Low Energy (“LE”), Z-Wave, ZigBee, etc., and/or low power wide-area network(s) (“LPWANs”), such as LoRaWAN, SigFox, etc.

FIG. 8B is an example of camera locations and fields of view for the example autonomous vehicle 800 of FIG. 8A, in accordance with some embodiments of the present disclosure. The cameras and respective fields of view are one example embodiment and are not intended to be limiting. For example, additional and/or alternative cameras may be included and/or the cameras may be located at different locations on the vehicle 800.

The camera types for the cameras may include, but are not limited to, digital cameras that may be adapted for use with the components and/or systems of the vehicle 800. The camera(s) may operate at automotive safety integrity level (ASIL) B and/or at another ASIL. The camera types may be capable of any image capture rate, such as 60 frames per second (fps), 120 fps, 240 fps, etc., depending on the embodiment. The cameras may be capable of using rolling shutters, global shutters, another type of shutter, or a combination thereof. In some examples, the color filter array may include a red clear clear clear (RCCC) color filter array, a red clear clear blue (RCCB) color filter array, a red blue green clear (RBGC) color filter array, a Foveon X3 color filter array, a Bayer sensors (RGGB) color filter array, a monochrome sensor color filter array, and/or another type of color filter array. In some embodiments, clear pixel cameras, such as cameras with an RCCC, an RCCB, and/or an RBGC color filter array, may be used in an effort to increase light sensitivity.

In some examples, one or more of the camera(s) may be used to perform advanced driver assistance systems (ADAS) functions (e.g., as part of a redundant or fail-safe design). For example, a Multi-Function Mono Camera may be installed to provide functions including lane departure warning, traffic sign assist and intelligent headlamp control. One or more of the camera(s) (e.g., all of the cameras) may record and provide image data (e.g., video) simultaneously.

One or more of the cameras may be mounted in a mounting assembly, such as a custom designed (three dimensional (“3D”) printed) assembly, in order to cut out stray light and reflections from within the car (e.g., reflections from the dashboard reflected in the windshield mirrors) which may interfere with the camera's image data capture abilities. With reference to wing-mirror mounting assemblies, the wing-mirror assemblies may be custom 3D printed so that the camera mounting plate matches the shape of the wing-mirror. In some examples, the camera(s) may be integrated into the wing-mirror. For side-view cameras, the camera(s) may also be integrated within the four pillars at each corner of the cabin.

Cameras with a field of view that include portions of the environment in front of the vehicle 800 (e.g., front-facing cameras) may be used for surround view, to help identify forward facing paths and obstacles, as well aid in, with the help of one or more controllers 836 and/or control SoCs, providing information critical to generating an occupancy grid and/or determining the preferred vehicle paths. Front-facing cameras may be used to perform many of the same ADAS functions as LIDAR, including emergency braking, pedestrian detection, and collision avoidance. Front-facing cameras may also be used for ADAS functions and systems including Lane Departure Warnings (“LDW”), Autonomous Cruise Control (“ACC”), and/or other functions such as traffic sign recognition.

A variety of cameras may be used in a front-facing configuration, including, for example, a monocular camera platform that includes a complementary metal oxide semiconductor (“CMOS”) color imager. Another example may be a wide-view camera(s) 870 that may be used to perceive objects coming into view from the periphery (e.g., pedestrians, crossing traffic or bicycles). Although only one wide-view camera is illustrated in FIG. 8B, there may be any number (including zero) of wide-view cameras 870 on the vehicle 800. In addition, any number of long-range camera(s) 898 (e.g., a long-view stereo camera pair) may be used for depth-based object detection, especially for objects for which a neural network has not yet been trained. The long-range camera(s) 898 may also be used for object detection and classification, as well as basic object tracking.

Any number of stereo cameras 868 may also be included in a front-facing configuration. In at least one embodiment, one or more of stereo camera(s) 868 may include an integrated control unit comprising a scalable processing unit, which may provide a programmable logic (“FPGA”) and a multi-core micro-processor with an integrated Controller Area Network (“CAN”) or Ethernet interface on a single chip. Such a unit may be used to generate a 3D map of the vehicle's environment, including a distance estimate for all the points in the image. An alternative stereo camera(s) 868 may include a compact stereo vision sensor(s) that may include two camera lenses (one each on the left and right) and an image processing chip that may measure the distance from the vehicle to the target object and use the generated information (e.g., metadata) to activate the autonomous emergency braking and lane departure warning functions. Other types of stereo camera(s) 868 may be used in addition to, or alternatively from, those described herein.

Cameras with a field of view that include portions of the environment to the side of the vehicle 800 (e.g., side-view cameras) may be used for surround view, providing information used to create and update the occupancy grid, as well as to generate side impact collision warnings. For example, surround camera(s) 874 (e.g., four surround cameras 874 as illustrated in FIG. 8B) may be positioned to on the vehicle 800. The surround camera(s) 874 may include wide-view camera(s) 870, fisheye camera(s), 360 degree camera(s), and/or the like. Four example, four fisheye cameras may be positioned on the vehicle's front, rear, and sides. In an alternative arrangement, the vehicle may use three surround camera(s) 874 (e.g., left, right, and rear), and may leverage one or more other camera(s) (e.g., a forward-facing camera) as a fourth surround view camera.

Cameras with a field of view that include portions of the environment to the rear of the vehicle 800 (e.g., rear-view cameras) may be used for park assistance, surround view, rear collision warnings, and creating and updating the occupancy grid. A wide variety of cameras may be used including, but not limited to, cameras that are also suitable as a front-facing camera(s) (e.g., long-range and/or mid-range camera(s) 898, stereo camera(s) 868), infrared camera(s) 872, etc.), as described herein.

FIG. 8C is a block diagram of an example system architecture for the example autonomous vehicle 800 of FIG. 8A, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory.

Each of the components, features, and systems of the vehicle 800 in FIG. 8C are illustrated as being connected via bus 802. The bus 802 may include a Controller Area Network (CAN) data interface (alternatively referred to herein as a “CAN bus”). A CAN may be a network inside the vehicle 800 used to aid in control of various features and functionality of the vehicle 800, such as actuation of brakes, acceleration, braking, steering, windshield wipers, etc. A CAN bus may be configured to have dozens or even hundreds of nodes, each with its own unique identifier (e.g., a CAN ID). The CAN bus may be read to find steering wheel angle, ground speed, engine revolutions per minute (RPMs), button positions, and/or other vehicle status indicators. The CAN bus may be ASIL B compliant.

Although the bus 802 is described herein as being a CAN bus, this is not intended to be limiting. For example, in addition to, or alternatively from, the CAN bus, FlexRay and/or Ethernet may be used. Additionally, although a single line is used to represent the bus 802, this is not intended to be limiting. For example, there may be any number of busses 802, which may include one or more CAN busses, one or more FlexRay busses, one or more Ethernet busses, and/or one or more other types of busses using a different protocol. In some examples, two or more busses 802 may be used to perform different functions, and/or may be used for redundancy. For example, a first bus 802 may be used for collision avoidance functionality and a second bus 802 may be used for actuation control. In any example, each bus 802 may communicate with any of the components of the vehicle 800, and two or more busses 802 may communicate with the same components. In some examples, each SoC 804, each controller 836, and/or each computer within the vehicle may have access to the same input data (e.g., inputs from sensors of the vehicle 800), and may be connected to a common bus, such the CAN bus.

The vehicle 800 may include one or more controller(s) 836, such as those described herein with respect to FIG. 8A. The controller(s) 836 may be used for a variety of functions. The controller(s) 836 may be coupled to any of the various other components and systems of the vehicle 800, and may be used for control of the vehicle 800, artificial intelligence of the vehicle 800, infotainment for the vehicle 800, and/or the like.

The vehicle 800 may include a system(s) on a chip (SoC) 804. The SoC 804 may include CPU(s) 806, GPU(s) 808, processor(s) 810, cache(s) 812, accelerator(s) 814, data store(s) 816, and/or other components and features not illustrated. The SoC(s) 804 may be used to control the vehicle 800 in a variety of platforms and systems. For example, the SoC(s) 804 may be combined in a system (e.g., the system of the vehicle 800) with an HD map 822 which may obtain map refreshes and/or updates via a network interface 824 from one or more servers (e.g., server(s) 878 of FIG. 8D).

The CPU(s) 806 may include a CPU cluster or CPU complex (alternatively referred to herein as a “CCPLEX”). The CPU(s) 806 may include multiple cores and/or L2 caches. For example, in some embodiments, the CPU(s) 806 may include eight cores in a coherent multi-processor configuration. In some embodiments, the CPU(s) 806 may include four dual-core clusters where each cluster has a dedicated L2 cache (e.g., a 2 MB L2 cache). The CPU(s) 806 (e.g., the CCPLEX) may be configured to support simultaneous cluster operation enabling any combination of the clusters of the CPU(s) 806 to be active at any given time.

The CPU(s) 806 may implement power management capabilities that include one or more of the following features: individual hardware blocks may be clock-gated automatically when idle to save dynamic power; each core clock may be gated when the core is not actively executing instructions due to execution of WFI/WFE instructions; each core may be independently power-gated; each core cluster may be independently clock-gated when all cores are clock-gated or power-gated; and/or each core cluster may be independently power-gated when all cores are power-gated. The CPU(s) 806 may further implement an enhanced algorithm for managing power states, where allowed power states and expected wakeup times are specified, and the hardware/microcode determines the best power state to enter for the core, cluster, and CCPLEX. The processing cores may support simplified power state entry sequences in software with the work offloaded to microcode.

The GPU(s) 808 may include an integrated GPU (alternatively referred to herein as an “iGPU”). The GPU(s) 808 may be programmable and may be efficient for parallel workloads. The GPU(s) 808, in some examples, may use an enhanced tensor instruction set. The GPU(s) 808 may include one or more streaming microprocessors, where each streaming microprocessor may include an L1 cache (e.g., an L1 cache with at least 96 KB storage capacity), and two or more of the streaming microprocessors may share an L2 cache (e.g., an L2 cache with a 512 KB storage capacity). In some embodiments, the GPU(s) 808 may include at least eight streaming microprocessors. The GPU(s) 808 may use compute application programming interface(s) (API(s)). In addition, the GPU(s) 808 may use one or more parallel computing platforms and/or programming models (e.g., NVIDIA's CUDA).

The GPU(s) 808 may be power-optimized for best performance in automotive and embedded use cases. For example, the GPU(s) 808 may be fabricated on a Fin field-effect transistor (FinFET). However, this is not intended to be limiting and the GPU(s) 808 may be fabricated using other semiconductor manufacturing processes. Each streaming microprocessor may incorporate a number of mixed-precision processing cores partitioned into multiple blocks. For example, and without limitation, 64 PF32 cores and 32 PF64 cores may be partitioned into four processing blocks. In such an example, each processing block may be allocated 16 FP32 cores, 8 FP64 cores, 16 INT32 cores, two mixed-precision NVIDIA TENSOR COREs for deep learning matrix arithmetic, an L0 instruction cache, a warp scheduler, a dispatch unit, and/or a 64 KB register file. In addition, the streaming microprocessors may include independent parallel integer and floating-point data paths to provide for efficient execution of workloads with a mix of computation and addressing calculations. The streaming microprocessors may include independent thread scheduling capability to enable finer-grain synchronization and cooperation between parallel threads. The streaming microprocessors may include a combined L1 data cache and shared memory unit in order to improve performance while simplifying programming.

The GPU(s) 808 may include a high bandwidth memory (HBM) and/or a 16 GB HBM2 memory subsystem to provide, in some examples, about 900 GB/second peak memory bandwidth. In some examples, in addition to, or alternatively from, the HBM memory, a synchronous graphics random-access memory (SGRAM) may be used, such as a graphics double data rate type five synchronous random-access memory (GDDR5).

The GPU(s) 808 may include unified memory technology including access counters to allow for more accurate migration of memory pages to the processor that accesses them most frequently, thereby improving efficiency for memory ranges shared between processors. In some examples, address translation services (ATS) support may be used to allow the GPU(s) 808 to access the CPU(s) 806 page tables directly. In such examples, when the GPU(s) 808 memory management unit (MMU) experiences a miss, an address translation request may be transmitted to the CPU(s) 806. In response, the CPU(s) 806 may look in its page tables for the virtual-to-physical mapping for the address and transmits the translation back to the GPU(s) 808. As such, unified memory technology may allow a single unified virtual address space for memory of both the CPU(s) 806 and the GPU(s) 808, thereby simplifying the GPU(s) 808 programming and porting of applications to the GPU(s) 808.

In addition, the GPU(s) 808 may include an access counter that may keep track of the frequency of access of the GPU(s) 808 to memory of other processors. The access counter may help ensure that memory pages are moved to the physical memory of the processor that is accessing the pages most frequently.

The SoC(s) 804 may include any number of cache(s) 812, including those described herein. For example, the cache(s) 812 may include an L3 cache that is available to both the CPU(s) 806 and the GPU(s) 808 (e.g., that is connected both the CPU(s) 806 and the GPU(s) 808). The cache(s) 812 may include a write-back cache that may keep track of states of lines, such as by using a cache coherence protocol (e.g., MEI, MESI, MSI, etc.). The L3 cache may include 4 MB or more, depending on the embodiment, although smaller cache sizes may be used.

The SoC(s) 804 may include an arithmetic logic unit(s) (ALU(s)) which may be leveraged in performing processing with respect to any of the variety of tasks or operations of the vehicle 800—such as processing DNNs. In addition, the SoC(s) 804 may include a floating point unit(s) (FPU(s))—or other math coprocessor or numeric coprocessor types—for performing mathematical operations within the system. For example, the SoC(s) 804 may include one or more FPUs integrated as execution units within a CPU(s) 806 and/or GPU(s) 808.

The SoC(s) 804 may include one or more accelerators 814 (e.g., hardware accelerators, software accelerators, or a combination thereof). For example, the SoC(s) 804 may include a hardware acceleration cluster that may include optimized hardware accelerators and/or large on-chip memory. The large on-chip memory (e.g., 4 MB of SRAM), may enable the hardware acceleration cluster to accelerate neural networks and other calculations. The hardware acceleration cluster may be used to complement the GPU(s) 808 and to off-load some of the tasks of the GPU(s) 808 (e.g., to free up more cycles of the GPU(s) 808 for performing other tasks). As an example, the accelerator(s) 814 may be used for targeted workloads (e.g., perception, convolutional neural networks (CNNs), etc.) that are stable enough to be amenable to acceleration. The term “CNN,” as used herein, may include all types of CNNs, including region-based or regional convolutional neural networks (RCNNs) and Fast RCNNs (e.g., as used for object detection).

The accelerator(s) 814 (e.g., the hardware acceleration cluster) may include a deep learning accelerator(s) (DLA). The DLA(s) may include one or more Tensor processing units (TPUs) that may be configured to provide an additional ten trillion operations per second for deep learning applications and inferencing. The TPUs may be accelerators configured to, and optimized for, performing image processing functions (e.g., for CNNs, RCNNs, etc.). The DLA(s) may further be optimized for a specific set of neural network types and floating point operations, as well as inferencing. The design of the DLA(s) may provide more performance per millimeter than a general-purpose GPU, and vastly exceeds the performance of a CPU. The TPU(s) may perform several functions, including a single-instance convolution function, supporting, for example, INT8, INT16, and FP16 data types for both features and weights, as well as post-processor functions.

The DLA(s) may quickly and efficiently execute neural networks, especially CNNs, on processed or unprocessed data for any of a variety of functions, including, for example and without limitation: a CNN for object identification and detection using data from camera sensors; a CNN for distance estimation using data from camera sensors; a CNN for emergency vehicle detection and identification and detection using data from microphones; a CNN for facial recognition and vehicle owner identification using data from camera sensors; and/or a CNN for security and/or safety related events.

The DLA(s) may perform any function of the GPU(s) 808, and by using an inference accelerator, for example, a designer may target either the DLA(s) or the GPU(s) 808 for any function. For example, the designer may focus processing of CNNs and floating point operations on the DLA(s) and leave other functions to the GPU(s) 808 and/or other accelerator(s) 814.

The accelerator(s) 814 (e.g., the hardware acceleration cluster) may include a programmable vision accelerator(s) (PVA), which may alternatively be referred to herein as a computer vision accelerator. The PVA(s) may be designed and configured to accelerate computer vision algorithms for the advanced driver assistance systems (ADAS), autonomous driving, and/or augmented reality (AR) and/or virtual reality (VR) applications. The PVA(s) may provide a balance between performance and flexibility. For example, each PVA(s) may include, for example and without limitation, any number of reduced instruction set computer (RISC) cores, direct memory access (DMA), and/or any number of vector processors.

The RISC cores may interact with image sensors (e.g., the image sensors of any of the cameras described herein), image signal processor(s), and/or the like. Each of the RISC cores may include any amount of memory. The RISC cores may use any of a number of protocols, depending on the embodiment. In some examples, the RISC cores may execute a real-time operating system (RTOS). The RISC cores may be implemented using one or more integrated circuit devices, application specific integrated circuits (ASICs), and/or memory devices. For example, the RISC cores may include an instruction cache and/or a tightly coupled RAM.

The DMA may enable components of the PVA(s) to access the system memory independently of the CPU(s) 806. The DMA may support any number of features used to provide optimization to the PVA including, but not limited to, supporting multi-dimensional addressing and/or circular addressing. In some examples, the DMA may support up to six or more dimensions of addressing, which may include block width, block height, block depth, horizontal block stepping, vertical block stepping, and/or depth stepping.

The vector processors may be programmable processors that may be designed to efficiently and flexibly execute programming for computer vision algorithms and provide signal processing capabilities. In some examples, the PVA may include a PVA core and two vector processing subsystem partitions. The PVA core may include a processor subsystem, DMA engine(s) (e.g., two DMA engines), and/or other peripherals. The vector processing subsystem may operate as the primary processing engine of the PVA, and may include a vector processing unit (VPU), an instruction cache, and/or vector memory (e.g., VMEM). A VPU core may include a digital signal processor such as, for example, a single instruction, multiple data (SIMD), very long instruction word (VLIW) digital signal processor. The combination of the SIMD and VLIW may enhance throughput and speed.

Each of the vector processors may include an instruction cache and may be coupled to dedicated memory. As a result, in some examples, each of the vector processors may be configured to execute independently of the other vector processors. In other examples, the vector processors that are included in a particular PVA may be configured to employ data parallelism. For example, in some embodiments, the plurality of vector processors included in a single PVA may execute the same computer vision algorithm, but on different regions of an image. In other examples, the vector processors included in a particular PVA may simultaneously execute different computer vision algorithms, on the same image, or even execute different algorithms on sequential images or portions of an image. Among other things, any number of PVAs may be included in the hardware acceleration cluster and any number of vector processors may be included in each of the PVAs. In addition, the PVA(s) may include additional error correcting code (ECC) memory, to enhance overall system safety.

The accelerator(s) 814 (e.g., the hardware acceleration cluster) may include a computer vision network on-chip and SRAM, for providing a high-bandwidth, low latency SRAM for the accelerator(s) 814. In some examples, the on-chip memory may include at least 4 MB SRAM, consisting of, for example and without limitation, eight field-configurable memory blocks, that may be accessible by both the PVA and the DLA. Each pair of memory blocks may include an advanced peripheral bus (APB) interface, configuration circuitry, a controller, and a multiplexer. Any type of memory may be used. The PVA and DLA may access the memory via a backbone that provides the PVA and DLA with high-speed access to memory. The backbone may include a computer vision network on-chip that interconnects the PVA and the DLA to the memory (e.g., using the APB).

The computer vision network on-chip may include an interface that determines, before transmission of any control signal/address/data, that both the PVA and the DLA provide ready and valid signals. Such an interface may provide for separate phases and separate channels for transmitting control signals/addresses/data, as well as burst-type communications for continuous data transfer. This type of interface may comply with ISO 26262 or IEC 61508 standards, although other standards and protocols may be used.

In some examples, the SoC(s) 804 may include a real-time ray-tracing hardware accelerator, such as described in U.S. patent application Ser. No. 16/101,232, filed on Aug. 10, 2018. The real-time ray-tracing hardware accelerator may be used to quickly and efficiently determine the positions and extents of objects (e.g., within a world model), to generate real-time visualization simulations, for RADAR signal interpretation, for sound propagation synthesis and/or analysis, for simulation of SONAR systems, for general wave propagation simulation, for comparison to LIDAR data for purposes of localization and/or other functions, and/or for other uses. In some embodiments, one or more tree traversal units (TTUs) may be used for executing one or more ray-tracing related operations.

The accelerator(s) 814 (e.g., the hardware accelerator cluster) have a wide array of uses for autonomous driving. The PVA may be a programmable vision accelerator that may be used for key processing stages in ADAS and autonomous vehicles. The PVA's capabilities are a good match for algorithmic domains needing predictable processing, at low power and low latency. In other words, the PVA performs well on semi-dense or dense regular computation, even on small data sets, which need predictable run-times with low latency and low power. Thus, in the context of platforms for autonomous vehicles, the PVAs are designed to run classic computer vision algorithms, as they are efficient at object detection and operating on integer math.

For example, according to one embodiment of the technology, the PVA is used to perform computer stereo vision. A semi-global matching-based algorithm may be used in some examples, although this is not intended to be limiting. Many applications for Level 3-5 autonomous driving require motion estimation/stereo matching on-the-fly (e.g., structure from motion, pedestrian recognition, lane detection, etc.). The PVA may perform computer stereo vision function on inputs from two monocular cameras.

In some examples, the PVA may be used to perform dense optical flow. According to process raw RADAR data (e.g., using a 4D Fast Fourier Transform) to provide Processed RADAR. In other examples, the PVA is used for time of flight depth processing, by processing raw time of flight data to provide processed time of flight data, for example.

The DLA may be used to run any type of network to enhance control and driving safety, including for example, a neural network that outputs a measure of confidence for each object detection. Such a confidence value may be interpreted as a probability, or as providing a relative “weight” of each detection compared to other detections. This confidence value enables the system to make further decisions regarding which detections should be considered as true positive detections rather than false positive detections. For example, the system may set a threshold value for the confidence and consider only the detections exceeding the threshold value as true positive detections. In an automatic emergency braking (AEB) system, false positive detections would cause the vehicle to automatically perform emergency braking, which is obviously undesirable. Therefore, only the most confident detections should be considered as triggers for AEB. The DLA may run a neural network for regressing the confidence value. The neural network may take as its input at least some subset of parameters, such as bounding box dimensions, ground plane estimate obtained (e.g. from another subsystem), inertial measurement unit (IMU) sensor 866 output that correlates with the vehicle 800 orientation, distance, 3D location estimates of the object obtained from the neural network and/or other sensors (e.g., LIDAR sensor(s) 864 or RADAR sensor(s) 860), among others.

The SoC(s) 804 may include data store(s) 816 (e.g., memory). The data store(s) 816 may be on-chip memory of the SoC(s) 804, which may store neural networks to be executed on the GPU and/or the DLA. In some examples, the data store(s) 816 may be large enough in capacity to store multiple instances of neural networks for redundancy and safety. The data store(s) 812 may comprise L2 or L3 cache(s) 812. Reference to the data store(s) 816 may include reference to the memory associated with the PVA, DLA, and/or other accelerator(s) 814, as described herein.

The SoC(s) 804 may include one or more processor(s) 810 (e.g., embedded processors). The processor(s) 810 may include a boot and power management processor that may be a dedicated processor and subsystem to handle boot power and management functions and related security enforcement. The boot and power management processor may be a part of the SoC(s) 804 boot sequence and may provide runtime power management services. The boot power and management processor may provide clock and voltage programming, assistance in system low power state transitions, management of SoC(s) 804 thermals and temperature sensors, and/or management of the SoC(s) 804 power states. Each temperature sensor may be implemented as a ring-oscillator whose output frequency is proportional to temperature, and the SoC(s) 804 may use the ring-oscillators to detect temperatures of the CPU(s) 806, GPU(s) 808, and/or accelerator(s) 814. If temperatures are determined to exceed a threshold, the boot and power management processor may enter a temperature fault routine and put the SoC(s) 804 into a lower power state and/or put the vehicle 800 into a chauffeur to safe stop mode (e.g., bring the vehicle 800 to a safe stop).

The processor(s) 810 may further include a set of embedded processors that may serve as an audio processing engine. The audio processing engine may be an audio subsystem that enables full hardware support for multi-channel audio over multiple interfaces, and a broad and flexible range of audio I/O interfaces. In some examples, the audio processing engine is a dedicated processor core with a digital signal processor with dedicated RAM.

The processor(s) 810 may further include an always on processor engine that may provide necessary hardware features to support low power sensor management and wake use cases. The always on processor engine may include a processor core, a tightly coupled RAM, supporting peripherals (e.g., timers and interrupt controllers), various I/O controller peripherals, and routing logic.

The processor(s) 810 may further include a safety cluster engine that includes a dedicated processor subsystem to handle safety management for automotive applications. The safety cluster engine may include two or more processor cores, a tightly coupled RAM, support peripherals (e.g., timers, an interrupt controller, etc.), and/or routing logic. In a safety mode, the two or more cores may operate in a lockstep mode and function as a single core with comparison logic to detect any differences between their operations.

The processor(s) 810 may further include a real-time camera engine that may include a dedicated processor subsystem for handling real-time camera management.

The processor(s) 810 may further include a high-dynamic range signal processor that may include an image signal processor that is a hardware engine that is part of the camera processing pipeline.

The processor(s) 810 may include a video image compositor that may be a processing block (e.g., implemented on a microprocessor) that implements video post-processing functions needed by a video playback application to produce the final image for the player window. The video image compositor may perform lens distortion correction on wide-view camera(s) 870, surround camera(s) 874, and/or on in-cabin monitoring camera sensors. In-cabin monitoring camera sensor is preferably monitored by a neural network running on another instance of the Advanced SoC, configured to identify in cabin events and respond accordingly. An in-cabin system may perform lip reading to activate cellular service and place a phone call, dictate emails, change the vehicle's destination, activate or change the vehicle's infotainment system and settings, or provide voice-activated web surfing. Certain functions are available to the driver only when the vehicle is operating in an autonomous mode, and are disabled otherwise.

The video image compositor may include enhanced temporal noise reduction for both spatial and temporal noise reduction. For example, where motion occurs in a video, the noise reduction weights spatial information appropriately, decreasing the weight of information provided by adjacent frames. Where an image or portion of an image does not include motion, the temporal noise reduction performed by the video image compositor may use information from the previous image to reduce noise in the current image.

The video image compositor may also be configured to perform stereo rectification on input stereo lens frames. The video image compositor may further be used for user interface composition when the operating system desktop is in use, and the GPU(s) 808 is not required to continuously render new surfaces. Even when the GPU(s) 808 is powered on and active doing 3D rendering, the video image compositor may be used to offload the GPU(s) 808 to improve performance and responsiveness.

The SoC(s) 804 may further include a mobile industry processor interface (MIPI) camera serial interface for receiving video and input from cameras, a high-speed interface, and/or a video input block that may be used for camera and related pixel input functions. The SoC(s) 804 may further include an input/output controller(s) that may be controlled by software and may be used for receiving I/O signals that are uncommitted to a specific role.

The SoC(s) 804 may further include a broad range of peripheral interfaces to enable communication with peripherals, audio codecs, power management, and/or other devices. The SoC(s) 804 may be used to process data from cameras (e.g., connected over Gigabit Multimedia Serial Link and Ethernet), sensors (e.g., LIDAR sensor(s) 864, RADAR sensor(s) 860, etc. that may be connected over Ethernet), data from bus 802 (e.g., speed of vehicle 800, steering wheel position, etc.), data from GNSS sensor(s) 858 (e.g., connected over Ethernet or CAN bus). The SoC(s) 804 may further include dedicated high-performance mass storage controllers that may include their own DMA engines, and that may be used to free the CPU(s) 806 from routine data management tasks.

The SoC(s) 804 may be an end-to-end platform with a flexible architecture that spans automation levels 3-5, thereby providing a comprehensive functional safety architecture that leverages and makes efficient use of computer vision and ADAS techniques for diversity and redundancy, provides a platform for a flexible, reliable driving software stack, along with deep learning tools. The SoC(s) 804 may be faster, more reliable, and even more energy-efficient and space-efficient than conventional systems. For example, the accelerator(s) 814, when combined with the CPU(s) 806, the GPU(s) 808, and the data store(s) 816, may provide for a fast, efficient platform for level 3-5 autonomous vehicles.

The technology thus provides capabilities and functionality that cannot be achieved by conventional systems. For example, computer vision algorithms may be executed on CPUs, which may be configured using high-level programming language, such as the C programming language, to execute a wide variety of processing algorithms across a wide variety of visual data. However, CPUs are oftentimes unable to meet the performance requirements of many computer vision applications, such as those related to execution time and power consumption, for example. In particular, many CPUs are unable to execute complex object detection algorithms in real-time, which is a requirement of in-vehicle ADAS applications, and a requirement for practical Level 3-5 autonomous vehicles.

In contrast to conventional systems, by providing a CPU complex, GPU complex, and a hardware acceleration cluster, the technology described herein allows for multiple neural networks to be performed simultaneously and/or sequentially, and for the results to be combined together to enable Level 3-5 autonomous driving functionality. For example, a CNN executing on the DLA or dGPU (e.g., the GPU(s) 820) may include a text and word recognition, allowing the supercomputer to read and understand traffic signs, including signs for which the neural network has not been specifically trained. The DLA may further include a neural network that is able to identify, interpret, and provides semantic understanding of the sign, and to pass that semantic understanding to the path planning modules running on the CPU Complex.

As another example, multiple neural networks may be run simultaneously, as is required for Level 3, 4, or 5 driving. For example, a warning sign consisting of “Caution: flashing lights indicate icy conditions,” along with an electric light, may be independently or collectively interpreted by several neural networks. The sign itself may be identified as a traffic sign by a first deployed neural network (e.g., a neural network that has been trained), the text “Flashing lights indicate icy conditions” may be interpreted by a second deployed neural network, which informs the vehicle's path planning software (preferably executing on the CPU Complex) that when flashing lights are detected, icy conditions exist. The flashing light may be identified by operating a third deployed neural network over multiple frames, informing the vehicle's path-planning software of the presence (or absence) of flashing lights. All three neural networks may run simultaneously, such as within the DLA and/or on the GPU(s) 808.

In some examples, a CNN for facial recognition and vehicle owner identification may use data from camera sensors to identify the presence of an authorized driver and/or owner of the vehicle 800. The always on sensor processing engine may be used to unlock the vehicle when the owner approaches the driver door and turn on the lights, and, in security mode, to disable the vehicle when the owner leaves the vehicle. In this way, the SoC(s) 804 provide for security against theft and/or carjacking.

In another example, a CNN for emergency vehicle detection and identification may use data from microphones 896 to detect and identify emergency vehicle sirens. In contrast to conventional systems, that use general classifiers to detect sirens and manually extract features, the SoC(s) 804 use the CNN for classifying environmental and urban sounds, as well as classifying visual data. In a preferred embodiment, the CNN running on the DLA is trained to identify the relative closing speed of the emergency vehicle (e.g., by using the Doppler Effect). The CNN may also be trained to identify emergency vehicles specific to the local area in which the vehicle is operating, as identified by GNSS sensor(s) 858. Thus, for example, when operating in Europe the CNN will seek to detect European sirens, and when in the United States the CNN will seek to identify only North American sirens. Once an emergency vehicle is detected, a control program may be used to execute an emergency vehicle safety routine, slowing the vehicle, pulling over to the side of the road, parking the vehicle, and/or idling the vehicle, with the assistance of ultrasonic sensors 862, until the emergency vehicle(s) passes.

The vehicle may include a CPU(s) 818 (e.g., discrete CPU(s), or dCPU(s)), that may be coupled to the SoC(s) 804 via a high-speed interconnect (e.g., PCIe). The CPU(s) 818 may include an X86 processor, for example. The CPU(s) 818 may be used to perform any of a variety of functions, including arbitrating potentially inconsistent results between ADAS sensors and the SoC(s) 804, and/or monitoring the status and health of the controller(s) 836 and/or infotainment SoC 830, for example.

The vehicle 800 may include a GPU(s) 820 (e.g., discrete GPU(s), or dGPU(s)), that may be coupled to the SoC(s) 804 via a high-speed interconnect (e.g., NVIDIA's NVLINK). The GPU(s) 820 may provide additional artificial intelligence functionality, such as by executing redundant and/or different neural networks, and may be used to train and/or update neural networks based on input (e.g., sensor data) from sensors of the vehicle 800.

The vehicle 800 may further include the network interface 824 which may include one or more wireless antennas 826 (e.g., one or more wireless antennas for different communication protocols, such as a cellular antenna, a Bluetooth antenna, etc.). The network interface 824 may be used to enable wireless connectivity over the Internet with the cloud (e.g., with the server(s) 878 and/or other network devices), with other vehicles, and/or with computing devices (e.g., client devices of passengers). To communicate with other vehicles, a direct link may be established between the two vehicles and/or an indirect link may be established (e.g., across networks and over the Internet). Direct links may be provided using a vehicle-to-vehicle communication link. The vehicle-to-vehicle communication link may provide the vehicle 800 information about vehicles in proximity to the vehicle 800 (e.g., vehicles in front of, on the side of, and/or behind the vehicle 800). This functionality may be part of a cooperative adaptive cruise control functionality of the vehicle 800.

The network interface 824 may include a SoC that provides modulation and demodulation functionality and enables the controller(s) 836 to communicate over wireless networks. The network interface 824 may include a radio frequency front-end for up-conversion from baseband to radio frequency, and down conversion from radio frequency to baseband. The frequency conversions may be performed through well-known processes, and/or may be performed using super-heterodyne processes. In some examples, the radio frequency front end functionality may be provided by a separate chip. The network interface may include wireless functionality for communicating over LTE, WCDMA, UMTS, GSM, CDMA2000, Bluetooth, Bluetooth LE, Wi-Fi, Z-Wave, ZigBee, LoRaWAN, and/or other wireless protocols.

The vehicle 800 may further include data store(s) 828 which may include off-chip (e.g., off the SoC(s) 804) storage. The data store(s) 828 may include one or more storage elements including RAM, SRAM, DRAM, VRAM, Flash, hard disks, and/or other components and/or devices that may store at least one bit of data.

The vehicle 800 may further include GNSS sensor(s) 858. The GNSS sensor(s) 858 (e.g., GPS, assisted GPS sensors, differential GPS (DGPS) sensors, etc.), to assist in mapping, perception, occupancy grid generation, and/or path planning functions. Any number of GNSS sensor(s) 858 may be used, including, for example and without limitation, a GPS using a USB connector with an Ethernet to Serial (RS-232) bridge.

The vehicle 800 may further include RADAR sensor(s) 860. The RADAR sensor(s) 860 may be used by the vehicle 800 for long-range vehicle detection, even in darkness and/or severe weather conditions. RADAR functional safety levels may be ASIL B. The RADAR sensor(s) 860 may use the CAN and/or the bus 802 (e.g., to transmit data generated by the RADAR sensor(s) 860) for control and to access object tracking data, with access to Ethernet to access raw data in some examples. A wide variety of RADAR sensor types may be used. For example, and without limitation, the RADAR sensor(s) 860 may be suitable for front, rear, and side RADAR use. In some example, Pulse Doppler RADAR sensor(s) are used.

The RADAR sensor(s) 860 may include different configurations, such as long range with narrow field of view, short range with wide field of view, short range side coverage, etc. In some examples, long-range RADAR may be used for adaptive cruise control functionality. The long-range RADAR systems may provide a broad field of view realized by two or more independent scans, such as within a 250 m range. The RADAR sensor(s) 860 may help in distinguishing between static and moving objects, and may be used by ADAS systems for emergency brake assist and forward collision warning. Long-range RADAR sensors may include monostatic multimodal RADAR with multiple (e.g., six or more) fixed RADAR antennae and a high-speed CAN and FlexRay interface. In an example with six antennae, the central four antennae may create a focused beam pattern, designed to record the vehicle's 800 surroundings at higher speeds with minimal interference from traffic in adjacent lanes. The other two antennae may expand the field of view, making it possible to quickly detect vehicles entering or leaving the vehicle's 800 lane.

Mid-range RADAR systems may include, as an example, a range of up to 860 m (front) or 80 m (rear), and a field of view of up to 42 degrees (front) or 850 degrees (rear). Short-range RADAR systems may include, without limitation, RADAR sensors designed to be installed at both ends of the rear bumper. When installed at both ends of the rear bumper, such a RADAR sensor systems may create two beams that constantly monitor the blind spot in the rear and next to the vehicle.

Short-range RADAR systems may be used in an ADAS system for blind spot detection and/or lane change assist.

The vehicle 800 may further include ultrasonic sensor(s) 862. The ultrasonic sensor(s) 862, which may be positioned at the front, back, and/or the sides of the vehicle 800, may be used for park assist and/or to create and update an occupancy grid. A wide variety of ultrasonic sensor(s) 862 may be used, and different ultrasonic sensor(s) 862 may be used for different ranges of detection (e.g., 2.5 m, 4 m). The ultrasonic sensor(s) 862 may operate at functional safety levels of ASIL B.

The vehicle 800 may include LIDAR sensor(s) 864. The LIDAR sensor(s) 864 may be used for object and pedestrian detection, emergency braking, collision avoidance, and/or other functions. The LIDAR sensor(s) 864 may be functional safety level ASIL B. In some examples, the vehicle 800 may include multiple LIDAR sensors 864 (e.g., two, four, six, etc.) that may use Ethernet (e.g., to provide data to a Gigabit Ethernet switch).

In some examples, the LIDAR sensor(s) 864 may be capable of providing a list of objects and their distances for a 360-degree field of view. Commercially available LIDAR sensor(s) 864 may have an advertised range of approximately 800 m, with an accuracy of 2 cm-3 cm, and with support for a 800 Mbps Ethernet connection, for example. In some examples, one or more non-protruding LIDAR sensors 864 may be used. In such examples, the LIDAR sensor(s) 864 may be implemented as a small device that may be embedded into the front, rear, sides, and/or corners of the vehicle 800. The LIDAR sensor(s) 864, in such examples, may provide up to a 120-degree horizontal and 35-degree vertical field-of-view, with a 200 m range even for low-reflectivity objects. Front-mounted LIDAR sensor(s) 864 may be configured for a horizontal field of view between 45 degrees and 135 degrees.

In some examples, LIDAR technologies, such as 3D flash LIDAR, may also be used. 3D Flash LIDAR uses a flash of a laser as a transmission source, to illuminate vehicle surroundings up to approximately 200 m. A flash LIDAR unit includes a receptor, which records the laser pulse transit time and the reflected light on each pixel, which in turn corresponds to the range from the vehicle to the objects. Flash LIDAR may allow for highly accurate and distortion-free images of the surroundings to be generated with every laser flash. In some examples, four flash LIDAR sensors may be deployed, one at each side of the vehicle 800. Available 3D flash LIDAR systems include a solid-state 3D staring array LIDAR camera with no moving parts other than a fan (e.g., a non-scanning LIDAR device). The flash LIDAR device may use a 5 nanosecond class I (eye-safe) laser pulse per frame and may capture the reflected laser light in the form of 3D range point clouds and co-registered intensity data. By using flash LIDAR, and because flash LIDAR is a solid-state device with no moving parts, the LIDAR sensor(s) 864 may be less susceptible to motion blur, vibration, and/or shock.

The vehicle may further include IMU sensor(s) 866. The IMU sensor(s) 866 may be located at a center of the rear axle of the vehicle 800, in some examples. The IMU sensor(s) 866 may include, for example and without limitation, an accelerometer(s), a magnetometer(s), a gyroscope(s), a magnetic compass(es), and/or other sensor types. In some examples, such as in six-axis applications, the IMU sensor(s) 866 may include accelerometers and gyroscopes, while in nine-axis applications, the IMU sensor(s) 866 may include accelerometers, gyroscopes, and magnetometers.

In some embodiments, the IMU sensor(s) 866 may be implemented as a miniature, high performance GPS-Aided Inertial Navigation System (GPS/INS) that combines micro-electro-mechanical systems (MEMS) inertial sensors, a high-sensitivity GPS receiver, and advanced Kalman filtering algorithms to provide estimates of position, velocity, and attitude. As such, in some examples, the IMU sensor(s) 866 may enable the vehicle 800 to estimate heading without requiring input from a magnetic sensor by directly observing and correlating the changes in velocity from GPS to the IMU sensor(s) 866. In some examples, the IMU sensor(s) 866 and the GNSS sensor(s) 858 may be combined in a single integrated unit.

The vehicle may include microphone(s) 896 placed in and/or around the vehicle 800. The microphone(s) 896 may be used for emergency vehicle detection and identification, among other things.

The vehicle may further include any number of camera types, including stereo camera(s) 868, wide-view camera(s) 870, infrared camera(s) 872, surround camera(s) 874, long-range and/or mid-range camera(s) 898, and/or other camera types. The cameras may be used to capture image data around an entire periphery of the vehicle 800. The types of cameras used depends on the embodiments and requirements for the vehicle 800, and any combination of camera types may be used to provide the necessary coverage around the vehicle 800. In addition, the number of cameras may differ depending on the embodiment. For example, the vehicle may include six cameras, seven cameras, ten cameras, twelve cameras, and/or another number of cameras. The cameras may support, as an example and without limitation, Gigabit Multimedia Serial Link (GMSL) and/or Gigabit Ethernet. Each of the camera(s) is described with more detail herein with respect to FIG. 8A and FIG. 8B.

The vehicle 800 may further include vibration sensor(s) 842. The vibration sensor(s) 842 may measure vibrations of components of the vehicle, such as the axle(s). For example, changes in vibrations may indicate a change in road surfaces. In another example, when two or more vibration sensors 842 are used, the differences between the vibrations may be used to determine friction or slippage of the road surface (e.g., when the difference in vibration is between a power-driven axle and a freely rotating axle).

The vehicle 800 may include an ADAS system 838. The ADAS system 838 may include SoC, in some examples. The ADAS system 838 may include autonomous/adaptive/automatic cruise control (ACC), cooperative adaptive cruise control (CACC), forward crash warning (FCW), automatic emergency braking (AEB), lane departure warnings (LDW), lane keep assist (LKA), blind spot warning (BSW), rear cross-traffic warning (RCTW), collision warning systems (CWS), lane centering (LC), and/or other features and functionality.

The ACC systems may use RADAR sensor(s) 860, LIDAR sensor(s) 864, and/or a camera(s). The ACC systems may include longitudinal ACC and/or lateral ACC. Longitudinal ACC monitors and controls the distance to the vehicle immediately ahead of the vehicle 800 and automatically adjust the vehicle speed to maintain a safe distance from vehicles ahead. Lateral ACC performs distance keeping, and advises the vehicle 800 to change lanes when necessary. Lateral ACC is related to other ADAS applications such as LCA and CWS.

CACC uses information from other vehicles that may be received via the network interface 824 and/or the wireless antenna(s) 826 from other vehicles via a wireless link, or indirectly, over a network connection (e.g., over the Internet). Direct links may be provided by a vehicle-to-vehicle (V2V) communication link, while indirect links may be infrastructure-to-vehicle (12V) communication link. In general, the V2V communication concept provides information about the immediately preceding vehicles (e.g., vehicles immediately ahead of and in the same lane as the vehicle 800), while the 12V communication concept provides information about traffic further ahead. CACC systems may include either or both I2V and V2V information sources. Given the information of the vehicles ahead of the vehicle 800, CACC may be more reliable and it has potential to improve traffic flow smoothness and reduce congestion on the road.

FCW systems are designed to alert the driver to a hazard, so that the driver may take corrective action. FCW systems use a front-facing camera and/or RADAR sensor(s) 860, coupled to a dedicated processor, DSP, FPGA, and/or ASIC, that is electrically coupled to driver feedback, such as a display, speaker, and/or vibrating component. FCW systems may provide a warning, such as in the form of a sound, visual warning, vibration and/or a quick brake pulse.

AEB systems detect an impending forward collision with another vehicle or other object, and may automatically apply the brakes if the driver does not take corrective action within a specified time or distance parameter. AEB systems may use front-facing camera(s) and/or RADAR sensor(s) 860, coupled to a dedicated processor, DSP, FPGA, and/or ASIC. When the AEB system detects a hazard, it typically first alerts the driver to take corrective action to avoid the collision and, if the driver does not take corrective action, the AEB system may automatically apply the brakes in an effort to prevent, or at least mitigate, the impact of the predicted collision. AEB systems, may include techniques such as dynamic brake support and/or crash imminent braking.

LDW systems provide visual, audible, and/or tactile warnings, such as steering wheel or seat vibrations, to alert the driver when the vehicle 800 crosses lane markings. A LDW system does not activate when the driver indicates an intentional lane departure, by activating a turn signal. LDW systems may use front-side facing cameras, coupled to a dedicated processor, DSP, FPGA, and/or ASIC, that is electrically coupled to driver feedback, such as a display, speaker, and/or vibrating component.

LKA systems are a variation of LDW systems. LKA systems provide steering input or braking to correct the vehicle 800 if the vehicle 800 starts to exit the lane.

BSW systems detects and warn the driver of vehicles in an automobile's blind spot. BSW systems may provide a visual, audible, and/or tactile alert to indicate that merging or changing lanes is unsafe. The system may provide an additional warning when the driver uses a turn signal. BSW systems may use rear-side facing camera(s) and/or RADAR sensor(s) 860, coupled to a dedicated processor, DSP, FPGA, and/or ASIC, that is electrically coupled to driver feedback, such as a display, speaker, and/or vibrating component.

RCTW systems may provide visual, audible, and/or tactile notification when an object is detected outside the rear-camera range when the vehicle 800 is backing up. Some RCTW systems include AEB to ensure that the vehicle brakes are applied to avoid a crash. RCTW systems may use one or more rear-facing RADAR sensor(s) 860, coupled to a dedicated processor, DSP, FPGA, and/or ASIC, that is electrically coupled to driver feedback, such as a display, speaker, and/or vibrating component.

Conventional ADAS systems may be prone to false positive results which may be annoying and distracting to a driver, but typically are not catastrophic, because the ADAS systems alert the driver and allow the driver to decide whether a safety condition truly exists and act accordingly. However, in an autonomous vehicle 800, the vehicle 800 itself must, in the case of conflicting results, decide whether to heed the result from a primary computer or a secondary computer (e.g., a first controller 836 or a second controller 836). For example, in some embodiments, the ADAS system 838 may be a backup and/or secondary computer for providing perception information to a backup computer rationality module. The backup computer rationality monitor may run a redundant diverse software on hardware components to detect faults in perception and dynamic driving tasks. Outputs from the ADAS system 838 may be provided to a supervisory MCU. If outputs from the primary computer and the secondary computer conflict, the supervisory MCU must determine how to reconcile the conflict to ensure safe operation.

In some examples, the primary computer may be configured to provide the supervisory MCU with a confidence score, indicating the primary computer's confidence in the chosen result. If the confidence score exceeds a threshold, the supervisory MCU may follow the primary computer's direction, regardless of whether the secondary computer provides a conflicting or inconsistent result. Where the confidence score does not meet the threshold, and where the primary and secondary computer indicate different results (e.g., the conflict), the supervisory MCU may arbitrate between the computers to determine the appropriate outcome.

The supervisory MCU may be configured to run a neural network(s) that is trained and configured to determine, based on outputs from the primary computer and the secondary computer, conditions under which the secondary computer provides false alarms. Thus, the neural network(s) in the supervisory MCU may learn when the secondary computer's output may be trusted, and when it cannot. For example, when the secondary computer is a RADAR-based FCW system, a neural network(s) in the supervisory MCU may learn when the FCW system is identifying metallic objects that are not, in fact, hazards, such as a drainage grate or manhole cover that triggers an alarm. Similarly, when the secondary computer is a camera-based LDW system, a neural network in the supervisory MCU may learn to override the LDW when bicyclists or pedestrians are present and a lane departure is, in fact, the safest maneuver. In embodiments that include a neural network(s) running on the supervisory MCU, the supervisory MCU may include at least one of a DLA or GPU suitable for running the neural network(s) with associated memory. In preferred embodiments, the supervisory MCU may comprise and/or be included as a component of the SoC(s) 804.

In other examples, ADAS system 838 may include a secondary computer that performs ADAS functionality using traditional rules of computer vision. As such, the secondary computer may use classic computer vision rules (if-then), and the presence of a neural network(s) in the supervisory MCU may improve reliability, safety and performance. For example, the diverse implementation and intentional non-identity makes the overall system more fault-tolerant, especially to faults caused by software (or software-hardware interface) functionality. For example, if there is a software bug or error in the software running on the primary computer, and the non-identical software code running on the secondary computer provides the same overall result, the supervisory MCU may have greater confidence that the overall result is correct, and the bug in software or hardware on primary computer is not causing material error.

In some examples, the output of the ADAS system 838 may be fed into the primary computer's perception block and/or the primary computer's dynamic driving task block. For example, if the ADAS system 838 indicates a forward crash warning due to an object immediately ahead, the perception block may use this information when identifying objects. In other examples, the secondary computer may have its own neural network which is trained and thus reduces the risk of false positives, as described herein.

The vehicle 800 may further include the infotainment SoC 830 (e.g., an in-vehicle infotainment system (IVI)). Although illustrated and described as a SoC, the infotainment system may not be a SoC, and may include two or more discrete components. The infotainment SoC 830 may include a combination of hardware and software that may be used to provide audio (e.g., music, a personal digital assistant, navigational instructions, news, radio, etc.), video (e.g., TV, movies, streaming, etc.), phone (e.g., hands-free calling), network connectivity (e.g., LTE, Wi-Fi, etc.), and/or information services (e.g., navigation systems, rear-parking assistance, a radio data system, vehicle related information such as fuel level, total distance covered, brake fuel level, oil level, door open/close, air filter information, etc.) to the vehicle 800. For example, the infotainment SoC 830 may radios, disk players, navigation systems, video players, USB and Bluetooth connectivity, carputers, in-car entertainment, Wi-Fi, steering wheel audio controls, hands free voice control, a heads-up display (HUD), an HMI display 834, a telematics device, a control panel (e.g., for controlling and/or interacting with various components, features, and/or systems), and/or other components. The infotainment SoC 830 may further be used to provide information (e.g., visual and/or audible) to a user(s) of the vehicle, such as information from the ADAS system 838, autonomous driving information such as planned vehicle maneuvers, trajectories, surrounding environment information (e.g., intersection information, vehicle information, road information, etc.), and/or other information.

The infotainment SoC 830 may include GPU functionality. The infotainment SoC 830 may communicate over the bus 802 (e.g., CAN bus, Ethernet, etc.) with other devices, systems, and/or components of the vehicle 800. In some examples, the infotainment SoC 830 may be coupled to a supervisory MCU such that the GPU of the infotainment system may perform some self-driving functions in the event that the primary controller(s) 836 (e.g., the primary and/or backup computers of the vehicle 800) fail. In such an example, the infotainment SoC 830 may put the vehicle 800 into a chauffeur to safe stop mode, as described herein.

The vehicle 800 may further include an instrument cluster 832 (e.g., a digital dash, an electronic instrument cluster, a digital instrument panel, etc.). The instrument cluster 832 may include a controller and/or supercomputer (e.g., a discrete controller or supercomputer). The instrument cluster 832 may include a set of instrumentation such as a speedometer, fuel level, oil pressure, tachometer, odometer, turn indicators, gearshift position indicator, seat belt warning light(s), parking-brake warning light(s), engine-malfunction light(s), airbag (SRS) system information, lighting controls, safety system controls, navigation information, etc. In some examples, information may be displayed and/or shared among the infotainment SoC 830 and the instrument cluster 832. In other words, the instrument cluster 832 may be included as part of the infotainment SoC 830, or vice versa.

FIG. 8D is a system diagram for communication between cloud-based server(s) and the example autonomous vehicle 800 of FIG. 8A, in accordance with some embodiments of the present disclosure. The system 876 may include server(s) 878, network(s) 890, and vehicles, including the vehicle 800. The server(s) 878 may include a plurality of GPUs 884(A)-884(H) (collectively referred to herein as GPUs 884), PCIe switches 882(A)-882(H) (collectively referred to herein as PCIe switches 882), and/or CPUs 880(A)-880(B) (collectively referred to herein as CPUs 880). The GPUs 884, the CPUs 880, and the PCIe switches may be interconnected with high-speed interconnects such as, for example and without limitation, NVLink interfaces 888 developed by NVIDIA and/or PCIe connections 886. In some examples, the GPUs 884 are connected via NVLink and/or NVSwitch SoC and the GPUs 884 and the PCIe switches 882 are connected via PCIe interconnects. Although eight GPUs 884, two CPUs 880, and two PCIe switches are illustrated, this is not intended to be limiting. Depending on the embodiment, each of the server(s) 878 may include any number of GPUs 884, CPUs 880, and/or PCIe switches. For example, the server(s) 878 may each include eight, sixteen, thirty-two, and/or more GPUs 884.

The server(s) 878 may receive, over the network(s) 890 and from the vehicles, image data representative of images showing unexpected or changed road conditions, such as recently commenced road-work. The server(s) 878 may transmit, over the network(s) 890 and to the vehicles, neural networks 892, updated neural networks 892, and/or map information 894, including information regarding traffic and road conditions. The updates to the map information 894 may include updates for the HD map 822, such as information regarding construction sites, potholes, detours, flooding, and/or other obstructions. In some examples, the neural networks 892, the updated neural networks 892, and/or the map information 894 may have resulted from new training and/or experiences represented in data received from any number of vehicles in the environment, and/or based on training performed at a datacenter (e.g., using the server(s) 878 and/or other servers).

The server(s) 878 may be used to train machine learning models (e.g., neural networks) based on training data. The training data may be generated by the vehicles, and/or may be generated in a simulation (e.g., using a game engine). In some examples, the training data is tagged (e.g., where the neural network benefits from supervised learning) and/or undergoes other pre-processing, while in other examples the training data is not tagged and/or pre-processed (e.g., where the neural network does not require supervised learning). Training may be executed according to any one or more classes of machine learning techniques, including, without limitation, classes such as: supervised training, semi-supervised training, unsupervised training, self-learning, reinforcement learning, federated learning, transfer learning, feature learning (including principal component and cluster analyses), multi-linear subspace learning, manifold learning, representation learning (including spare dictionary learning), rule-based machine learning, anomaly detection, and any variants or combinations therefor. Once the machine learning models are trained, the machine learning models may be used by the vehicles (e.g., transmitted to the vehicles over the network(s) 890, and/or the machine learning models may be used by the server(s) 878 to remotely monitor the vehicles.

In some examples, the server(s) 878 may receive data from the vehicles and apply the data to up-to-date real-time neural networks for real-time intelligent inferencing. The server(s) 878 may include deep-learning supercomputers and/or dedicated AI computers powered by GPU(s) 884, such as a DGX and DGX Station machines developed by NVIDIA. However, in some examples, the server(s) 878 may include deep learning infrastructure that use only CPU-powered datacenters.

The deep-learning infrastructure of the server(s) 878 may be capable of fast, real-time inferencing, and may use that capability to evaluate and verify the health of the processors, software, and/or associated hardware in the vehicle 800. For example, the deep-learning infrastructure may receive periodic updates from the vehicle 800, such as a sequence of images and/or objects that the vehicle 800 has located in that sequence of images (e.g., via computer vision and/or other machine learning object classification techniques). The deep-learning infrastructure may run its own neural network to identify the objects and compare them with the objects identified by the vehicle 800 and, if the results do not match and the infrastructure concludes that the AI in the vehicle 800 is malfunctioning, the server(s) 878 may transmit a signal to the vehicle 800 instructing a fail-safe computer of the vehicle 800 to assume control, notify the passengers, and complete a safe parking maneuver.

For inferencing, the server(s) 878 may include the GPU(s) 884 and one or more programmable inference accelerators (e.g., NVIDIA's TensorRT). The combination of GPU-powered servers and inference acceleration may make real-time responsiveness possible. In other examples, such as where performance is less critical, servers powered by CPUs, FPGAs, and other processors may be used for inferencing.

### Example Computing Device

FIG. 9 is a block diagram of an example computing device(s) 900 suitable for use in implementing some embodiments of the present disclosure. Computing device 900 may include an interconnect system 902 that directly or indirectly couples the following devices: memory 904, one or more central processing units (CPUs) 906, one or more graphics processing units (GPUs) 908, a communication interface 910, input/output (I/O) ports 912, input/output components 914, a power supply 916, one or more presentation components 918 (e.g., display(s)), and one or more logic units 920. In at least one embodiment, the computing device(s) 900 may comprise one or more virtual machines (VMs), and/or any of the components thereof may comprise virtual components (e.g., virtual hardware components). For non-limiting examples, one or more of the GPUs 908 may comprise one or more vGPUs, one or more of the CPUs 906 may comprise one or more vCPUs, and/or one or more of the logic units 920 may comprise one or more virtual logic units. As such, a computing device(s) 900 may include discrete components (e.g., a full GPU dedicated to the computing device 900), virtual components (e.g., a portion of a GPU dedicated to the computing device 900), or a combination thereof.

Although the various blocks of FIG. 9 are shown as connected via the interconnect system 902 with lines, this is not intended to be limiting and is for clarity only. For example, in some embodiments, a presentation component 918, such as a display device, may be considered an I/O component 914 (e.g., if the display is a touch screen). As another example, the CPUs 906 and/or GPUs 908 may include memory (e.g., the memory 904 may be representative of a storage device in addition to the memory of the GPUs 908, the CPUs 906, and/or other components). In other words, the computing device of FIG. 9 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 9.

The interconnect system 902 may represent one or more links or busses, such as an address bus, a data bus, a control bus, or a combination thereof. The interconnect system 902 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 906 may be directly connected to the memory 904. Further, the CPU 906 may be directly connected to the GPU 908. Where there is direct, or point-to-point connection between components, the interconnect system 902 may include a PCIe link to carry out the connection. In these examples, a PCI bus need not be included in the computing device 900.

The memory 904 may include any of a variety of computer-readable media. The computer-readable media may be any available media that may be accessed by the computing device 900. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 904 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 900. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 906 may be configured to execute at least some of the computer-readable instructions to control one or more components of the computing device 900 to perform one or more of the methods and/or processes described herein. The CPU(s) 906 may each include one or more cores (e.g., one, two, four, eight, twenty-eight, seventy-two, etc.) that are capable of handling a multitude of software threads simultaneously. The CPU(s) 906 may include any type of processor, and may include different types of processors depending on the type of computing device 900 implemented (e.g., processors with fewer cores for mobile devices and processors with more cores for servers). For example, depending on the type of computing device 900, the processor may be an Advanced RISC Machines (ARM) processor implemented using Reduced Instruction Set Computing (RISC) or an x86 processor implemented using Complex Instruction Set Computing (CISC). The computing device 900 may include one or more CPUs 906 in addition to one or more microprocessors or supplementary co-processors, such as math co-processors.

In addition to or alternatively from the CPU(s) 906, the GPU(s) 908 may be configured to execute at least some of the computer-readable instructions to control one or more components of the computing device 900 to perform one or more of the methods and/or processes described herein. One or more of the GPU(s) 908 may be an integrated GPU (e.g., with one or more of the CPU(s) 906 and/or one or more of the GPU(s) 908 may be a discrete GPU. In embodiments, one or more of the GPU(s) 908 may be a coprocessor of one or more of the CPU(s) 906. The GPU(s) 908 may be used by the computing device 900 to render graphics (e.g., 3D graphics) or perform general purpose computations. For example, the GPU(s) 908 may be used for General-Purpose computing on GPUs (GPGPU). The GPU(s) 908 may include hundreds or thousands of cores that are capable of handling hundreds or thousands of software threads simultaneously. The GPU(s) 908 may generate pixel data for output images in response to rendering commands (e.g., rendering commands from the CPU(s) 906 received via a host interface). The GPU(s) 908 may include graphics memory, such as display memory, for storing pixel data or any other suitable data, such as GPGPU data. The display memory may be included as part of the memory 904. The GPU(s) 908 may include two or more GPUs operating in parallel (e.g., via a link). The link may directly connect the GPUs (e.g., using NVLINK) or may connect the GPUs through a switch (e.g., using NVSwitch). When combined together, each GPU 908 may generate pixel data or GPGPU data for different portions of an output or for different outputs (e.g., a first GPU for a first image and a second GPU for a second image). Each GPU may include its own memory, or may share memory with other GPUs.

In addition to or alternatively from the CPU(s) 906 and/or the GPU(s) 908, the logic unit(s) 920 may be configured to execute at least some of the computer-readable instructions to control one or more components of the computing device 900 to perform one or more of the methods and/or processes described herein. In embodiments, the CPU(s) 906, the GPU(s) 908, and/or the logic unit(s) 920 may discretely or jointly perform any combination of the methods, processes and/or portions thereof. One or more of the logic units 920 may be part of and/or integrated in one or more of the CPU(s) 906 and/or the GPU(s) 908 and/or one or more of the logic units 920 may be discrete components or otherwise external to the CPU(s) 906 and/or the GPU(s) 908. In embodiments, one or more of the logic units 920 may be a coprocessor of one or more of the CPU(s) 906 and/or one or more of the GPU(s) 908.

Examples of the logic unit(s) 920 include one or more processing cores and/or components thereof, such as Data Processing Units (DPUs), Tensor Cores (TCs), Tensor Processing Units (TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 910 may include one or more receivers, transmitters, and/or transceivers that enable the computing device 900 to communicate with other computing devices via an electronic communication network, included wired and/or wireless communications. The communication interface 910 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 920 and/or communication interface 910 may include one or more data processing units (DPUs) to transmit data received over a network and/or through interconnect system 902 directly to (e.g., a memory of) one or more GPU(s) 908.

The I/O ports 912 may enable the computing device 900 to be logically coupled to other devices including the I/O components 914, the presentation component(s) 918, and/or other components, some of which may be built in to (e.g., integrated in) the computing device 900. Illustrative I/O components 914 include a microphone, mouse, keyboard, joystick, game pad, game controller, satellite dish, scanner, printer, wireless device, etc. The I/O components 914 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 900. The computing device 900 may be include depth cameras, such as stereoscopic camera systems, infrared camera systems, RGB camera systems, touchscreen technology, and combinations of these, for gesture detection and recognition. Additionally, the computing device 900 may include accelerometers or gyroscopes (e.g., as part of an inertia measurement unit (IMU)) that enable detection of motion. In some examples, the output of the accelerometers or gyroscopes may be used by the computing device 900 to render immersive augmented reality or virtual reality.

The power supply 916 may include a hard-wired power supply, a battery power supply, or a combination thereof. The power supply 916 may provide power to the computing device 900 to enable the components of the computing device 900 to operate.

The presentation component(s) 918 may include a display (e.g., a monitor, a touch screen, a television screen, a heads-up-display (HUD), other display types, or a combination thereof), speakers, and/or other presentation components. The presentation component(s) 918 may receive data from other components (e.g., the GPU(s) 908, the CPU(s) 906, DPUs, etc.), and output the data (e.g., as an image, video, sound, etc.).

### Example Data Center

FIG. 10 illustrates an example data center 1000 that may be used in at least one embodiments of the present disclosure. The data center 1000 may include a data center infrastructure layer 1010, a framework layer 1020, a software layer 1030, and/or an application layer 1040.

As shown in FIG. 10, the data center infrastructure layer 1010 may include a resource orchestrator 1012, grouped computing resources 1014, and node computing resources (“node C.R.s”) 1016(1)-1016(N), where “N” represents any whole, positive integer. In at least one embodiment, node C.R.s 1016(1)-1016(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, one or more node C.R.s from among node C.R.s 1016(1)-1016(N) may correspond to a server having one or more of the above-mentioned computing resources. In addition, in some embodiments, the node C.R.s 1016(1)-10161(N) may include one or more virtual components, such as vGPUs, vCPUs, and/or the like, and/or one or more of the node C.R.s 1016(1)-1016(N) may correspond to a virtual machine (VM).

In at least one embodiment, grouped computing resources 1014 may include separate groupings of node C.R.s 1016 housed within one or more racks (not shown), or many racks housed in data centers at various geographical locations (also not shown). Separate groupings of node C.R.s 1016 within grouped computing resources 1014 may include grouped compute, network, memory or storage resources that may be configured or allocated to support one or more workloads. In at least one embodiment, several node C.R.s 1016 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 1012 may configure or otherwise control one or more node C.R.s 1016(1)-1016(N) and/or grouped computing resources 1014. In at least one embodiment, resource orchestrator 1012 may include a software design infrastructure (SDI) management entity for the data center 1000. The resource orchestrator 1012 may include hardware, software, or some combination thereof.

In at least one embodiment, as shown in FIG. 10, framework layer 1020 may include a job scheduler 1033, a configuration manager 1034, a resource manager 1036, and/or a distributed file system 1038. The framework layer 1020 may include a framework to support software 1032 of software layer 1030 and/or one or more application(s) 1042 of application layer 1040. The software 1032 or application(s) 1042 may respectively include web-based service software or applications, such as those provided by Amazon Web Services, Google Cloud and Microsoft Azure. The framework layer 1020 may be, but is not limited to, a type of free and open-source software web application framework such as Apache Spark™ (hereinafter “Spark”) that may utilize distributed file system 1038 for large-scale data processing (e.g., “big data”). In at least one embodiment, job scheduler 1033 may include a Spark driver to facilitate scheduling of workloads supported by various layers of data center 1000. The configuration manager 1034 may be capable of configuring different layers such as software layer 1030 and framework layer 1020 including Spark and distributed file system 1038 for supporting large-scale data processing. The resource manager 1036 may be capable of managing clustered or grouped computing resources mapped to or allocated for support of distributed file system 1038 and job scheduler 1033. In at least one embodiment, clustered or grouped computing resources may include grouped computing resource 1014 at data center infrastructure layer 1010. The resource manager 1036 may coordinate with resource orchestrator 1012 to manage these mapped or allocated computing resources.

In at least one embodiment, software 1032 included in software layer 1030 may include software used by at least portions of node C.R.s 1016(1)-1016(N), grouped computing resources 1014, and/or distributed file system 1038 of framework layer 1020. One or more types of software may include, but are not limited to, Internet web page search software, e-mail virus scan software, database software, and streaming video content software.

In at least one embodiment, application(s) 1042 included in application layer 1040 may include one or more types of applications used by at least portions of node C.R.s 1016(1)-1016(N), grouped computing resources 1014, and/or distributed file system 1038 of framework layer 1020. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments.

In at least one embodiment, any of configuration manager 1034, resource manager 1036, and resource orchestrator 1012 may implement any number and type of self-modifying actions based on any amount and type of data acquired in any technically feasible fashion. Self-modifying actions may relieve a data center operator of data center 1000 from making possibly bad configuration decisions and possibly avoiding underutilized and/or poor performing portions of a data center.

The data center 1000 may include tools, services, software or other resources to train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 1000. In at least one embodiment, trained or deployed machine learning models corresponding to one or more neural networks may be used to infer or predict information using resources described above with respect to the data center 1000 by using weight parameters calculated through one or more training techniques, such as but not limited to those described herein.

In at least one embodiment, the data center 1000 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to train or performing inferencing of information, such as image recognition, speech recognition, or other artificial intelligence services.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 900 of FIG. 9—e.g., each device may include similar components, features, and/or functionality of the computing device(s) 900. In addition, where backend devices (e.g., servers, NAS, etc.) are implemented, the backend devices may be included as part of a data center 1000, an example of which is described in more detail herein with respect to FIG. 10.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 900 described herein with respect to FIG. 9. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

### Example Paragraphs

A. A method comprising: determining, based at least on sensor data generated using one or more sensors of a machine, a presence of one or more target regions within an environment, the one or more target regions including one or more target areas representative of one or more potential locations of one or more target objects; determining, based at least on a correlation associated with one or more points of the sensor data within the one or more target areas, that the one or more points correspond to at least one target object of the one or more target objects; based at least on the one or more points corresponding to the target object, tracking one or more predicted locations of the at least one target object responsive to one or more movements associated with the machine; and performing one or more operations associated with the machine based at least on the tracking of the one or more predicted locations of the at least one target object.

B. The method as recited in paragraph A, further comprising: determining, based at least on a second correlation associated with one or more second points of the sensor data within the one or more target areas, one or more second predicted locations of the at least one target object; and determining to track the one or more predicted locations instead of the one or more second predicted locations based at least on a first score associated with the correlation being greater than a second score associated with the second correlation.

C. The method as recited in any one of paragraphs A-B, further comprising: updating the one or more predicted locations of the at least one target object based at least on second sensor data obtained subsequent to the one or more movements; and performing one or more second operations associated with the machine based at least on the updating of the one or more predicted locations.

D. The method as recited in any one of paragraphs A-C, wherein the one or more operations associated with the machine are performed within a target region of the one or more target regions such that one or more confidence scores associated with one or more sensor measurements corresponding to the at least one target object are less than a threshold.

E. The method as recited in any one of paragraphs A-D, wherein the one or more target regions correspond to one or more parking spaces in the environment and the one or more potential locations represented using the one or more target areas correspond to one or more average locations of the one or more target objects in the one or more parking spaces.

F. The method as recited in any one of paragraphs A-E, wherein the one or more target objects correspond to one or more parking barriers, the one or more parking barriers including at least one of a wheel stop, a curb, or a ground lock.

G. The method as recited in any one of paragraphs A-F, wherein the determining that the one or more points correspond to the at least one target object comprises: generating, based at least on the one or more target areas and the one or more points, data indicating at least one of a proposed location or a proposed orientation associated with the at least one target object; calculating one or more metrics indicative of at least an alignment of the one or more points and the data; and determining whether the one or more points correspond to the at least one target object based at least on evaluating one or more values of the one or more metrics with respect to one or more thresholds.

H. The method as recited in any one of paragraphs A-G, further comprising: obtaining map data indicating one or more locations of the one or more target regions in the environment; and evaluating the sensor data with respect to the map data, wherein the determining the presence of one or more target regions within the environment is based at least on the evaluating.

I. The method as recited in any one of paragraphs A-H, further comprising: generating, using the sensor data, a map representing one or more locations corresponding to one or more detected objects in the environment, wherein the tracking of the one or more predicted locations of the at least one target object comprises tracking a location of an identifier on the map, the identifier corresponding to the at least one target object.

J. The method as recited in any one of paragraphs A-I, wherein: the one or more target objects are associated with one or more vertical dimensions that are less than a threshold vertical dimension, and the determining that the one or more points correspond to the at least one target object is further based at least on one or more vertical measurements associated with the one or more points being less than the threshold vertical dimension.

K. A system comprising: one or more processors to: determine, based at least on sensor data corresponding to one or more target regions in an environment, a probability associated with one or more target objects being disposed in one or more target areas within the one or more target regions; track one or more predicted locations corresponding to the one or more target objects based at least on the probability meeting or exceeding a threshold; and perform one or more operations associated with a machine within the one or more target regions based at least on the tracking of the one or more predicted locations.

L. The system as recited in paragraph k, wherein the determination of the probability associated with the one or more target objects being disposed in the one or more target areas comprises determining whether a number of points of the sensor data that correspond to the one or more target areas meets or exceeds a threshold.

M. The system as recited in any one of paragraphs K-L, the one or more processors further to determine one or more orientations of the one or more target objects based at least on an alignment associated with one or more points of the sensor data.

N. The system as recited in any one of paragraphs K-M, the one or more processors further to: update the one or more predicted locations of the one or more target objects based at least on second sensor data obtained subsequent to the performance of the one or more operations; and perform one or more second operations associated with the machine based at least on the update of the one or more predicted locations.

O. The system as recited in any one of paragraphs K-N, wherein the one or more target regions correspond to one or more parking spaces in the environment and the one or more target objects correspond to one or more parking barriers associated with the one or more parking spaces, the one or more parking barriers including at least one of a wheel stop, a curb, or a ground lock.

P. The system as recited in any one of paragraphs K-O, the one or more processors further to: obtain map data indicating one or more locations of the one or more target regions in the environment; and analyze the sensor data with respect to the map data, wherein the determination of the probability associated with the one or more target objects being disposed in the one or more target areas of the one or more target regions is based at least on the analysis.

Q. The system as recited in any one of paragraphs K-P, wherein the system is comprised in at least one of: a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system implemented using a robot; a system for performing one or more generative AI operations; a system for performing operations using a large language model; a system for performing operations using one or more vision language models (VLMs); a system for performing operations using one or more multi-modal language models; a system for performing one or more conversational AI operations; a system for generating synthetic data; a system for presenting at least one of virtual reality content, augmented reality content, or mixed reality content; a system incorporating one or more virtual machines (VMs); a system implemented at least partially in a data center; or a system implemented at least partially using cloud computing resources.

R. At least one processor comprising: processing circuitry to perform one or more operations associated with a machine based at least on tracking a predicted location of a target object in an environment responsive to performance of one or more previous operations associated with the machine, the predicted location of the target object at least one of determined or updated while the machine was positioned at one or more previous locations based at least on sensor data indicating a presence of one or more objects within a target region of the environment.

S. The processor as recited in paragraph R, wherein the target region includes one or more target spaces representative of one or more locations in which a probability of a detected object corresponding to the target object meets or exceeds a threshold based at least on the detected object being located within a target space of the one or more target spaces.

T. The processor as recited in any one of paragraphs R-S, wherein the processor is comprised in at least one of: a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system implemented using a robot; a system for performing one or more generative AI operations; a system for performing operations using a large language model; a system for performing operations using one or more vision language models (VLMs); a system for performing operations using one or more multi-modal language models; a system for performing one or more conversational AI operations; a system for generating synthetic data; a system for presenting at least one of virtual reality content, augmented reality content, or mixed reality content; a system incorporating one or more virtual machines (VMs); a system implemented at least partially in a data center; or a system implemented at least partially using cloud computing resources.

U. A system comprising: one or more processors to evaluate one or more region of interest (ROI) detection algorithms within a simulation that is rendered using one or more light transport simulation algorithms, the one or more ROI detection algorithms using known object characteristics within a ROI to perform ROI detection.

V. The system as recited in paragraph U, wherein the simulation is generated, at least in part, using a three-dimensional (3D) content collaboration platform for 3D assets.

W. The system as recited in any one of paragraphs U-V, wherein the 3D content collaboration platform for 3D assets uses OpenUSD.

What is claimed is:

1. A method comprising:
determining, based at least on sensor data generated using one or more sensors of a machine, a presence of one or more target regions within an environment, the one or more target regions including one or more target areas representative of one or more potential locations of one or more target objects;
determining, based at least on a correlation associated with one or more points of the sensor data within the one or more target areas, that the one or more points correspond to at least one target object of the one or more target objects;
based at least on the one or more points corresponding to the target object, tracking one or more predicted locations of the at least one target object responsive to one or more movements associated with the machine; and
performing one or more operations associated with the machine based at least on the tracking of the one or more predicted locations of the at least one target object.

2. The method of claim 1, further comprising:
determining, based at least on a second correlation associated with one or more second points of the sensor data within the one or more target areas, one or more second predicted locations of the at least one target object; and
determining to track the one or more predicted locations instead of the one or more second predicted locations based at least on a first score associated with the correlation being greater than a second score associated with the second correlation.

3. The method of claim 1, further comprising:
updating the one or more predicted locations of the at least one target object based at least on second sensor data obtained subsequent to the one or more movements; and
performing one or more second operations associated with the machine based at least on the updating of the one or more predicted locations.

4. The method of claim 1, wherein the one or more operations associated with the machine are performed within a target region of the one or more target regions such that one or more confidence scores associated with one or more sensor measurements corresponding to the at least one target object are less than a threshold.

5. The method of claim 1, wherein the one or more target regions correspond to one or more parking spaces in the environment and the one or more potential locations represented using the one or more target areas correspond to one or more average locations of the one or more target objects in the one or more parking spaces.

6. The method of claim 5, wherein the one or more target objects correspond to one or more parking barriers, the one or more parking barriers including at least one of a wheel stop, a curb, or a ground lock.

7. The method of claim 1, wherein the determining that the one or more points correspond to the at least one target object comprises:
generating, based at least on the one or more target areas and the one or more points, data indicating at least one of a proposed location or a proposed orientation associated with the at least one target object;
calculating one or more metrics indicative of at least an alignment of the one or more points and the data; and
determining whether the one or more points correspond to the at least one target object based at least on evaluating one or more values of the one or more metrics with respect to one or more thresholds.

8. The method of claim 1, further comprising:
obtaining map data indicating one or more locations of the one or more target regions in the environment; and
evaluating the sensor data with respect to the map data, wherein the determining the presence of one or more target regions within the environment is based at least on the evaluating.

9. The method of claim 1, further comprising:
generating, using the sensor data, a map representing one or more locations corresponding to one or more detected objects in the environment,
wherein the tracking of the one or more predicted locations of the at least one target object comprises tracking a location of an identifier on the map, the identifier corresponding to the at least one target object.

10. The method of claim 1, wherein:
the one or more target objects are associated with one or more vertical dimensions that are less than a threshold vertical dimension, and
the determining that the one or more points correspond to the at least one target object is further based at least on one or more vertical measurements associated with the one or more points being less than the threshold vertical dimension.

11. A system comprising:
one or more processors to:
determine, based at least on sensor data corresponding to one or more target regions in an environment, a probability associated with one or more target objects being disposed in one or more target areas within the one or more target regions;
track one or more predicted locations corresponding to the one or more target objects based at least on the probability meeting or exceeding a threshold; and
perform one or more operations associated with a machine within the one or more target regions based at least on the tracking of the one or more predicted locations.

12. The system of claim 11, wherein the determination of the probability associated with the one or more target objects being disposed in the one or more target areas comprises determining whether a number of points of the sensor data that correspond to the one or more target areas meets or exceeds a threshold.

13. The system of claim 11, the one or more processors further to determine one or more orientations of the one or more target objects based at least on an alignment associated with one or more points of the sensor data.

14. The system of claim 11, the one or more processors further to:
update the one or more predicted locations of the one or more target objects based at least on second sensor data obtained subsequent to the performance of the one or more operations; and
perform one or more second operations associated with the machine based at least on the update of the one or more predicted locations.

15. The system of claim 11, wherein the one or more target regions correspond to one or more parking spaces in the environment and the one or more target objects correspond to one or more parking barriers associated with the one or more parking spaces, the one or more parking barriers including at least one of a wheel stop, a curb, or a ground lock.

16. The system of claim 11, the one or more processors further to:
obtain map data indicating one or more locations of the one or more target regions in the environment; and
analyze the sensor data with respect to the map data, wherein the determination of the probability associated with the one or more target objects being disposed in the one or more target areas of the one or more target regions is based at least on the analysis.

17. The system of claim 11, wherein the system is comprised in at least one of:
a control system for an autonomous or semi-autonomous machine;
a perception system for an autonomous or semi-autonomous machine;
a system for performing one or more simulation operations;
a system for performing one or more digital twin operations;
a system for performing light transport simulation;
a system for performing collaborative content creation for 3D assets;
a system for performing one or more deep learning operations;
a system implemented using an edge device;
a system implemented using a robot;
a system for performing one or more generative AI operations;
a system for performing operations using a large language model;
a system for performing operations using one or more vision language models (VLMs);
a system for performing operations using one or more multi-modal language models;
a system for performing one or more conversational AI operations;
a system for generating synthetic data;
a system for presenting at least one of virtual reality content, augmented reality content, or mixed reality content;
a system incorporating one or more virtual machines (VMs);
a system implemented at least partially in a data center; or
a system implemented at least partially using cloud computing resources.

18. At least one processor comprising:
processing circuitry to perform one or more operations associated with a machine based at least on tracking a predicted location of a target object in an environment responsive to performance of one or more previous operations associated with the machine, the predicted location of the target object at least one of determined or updated while the machine was positioned at one or more previous locations based at least on sensor data indicating a presence of one or more objects within a target region of the environment.

19. The processor of claim 18, wherein the target region includes one or more target spaces representative of one or more locations in which a probability of a detected object corresponding to the target object meets or exceeds a threshold based at least on the detected object being located within a target space of the one or more target spaces.

20. The processor of claim 18, wherein the processor is comprised in at least one of:
a control system for an autonomous or semi-autonomous machine;
a perception system for an autonomous or semi-autonomous machine;
a system for performing one or more simulation operations;
a system for performing one or more digital twin operations;
a system for performing light transport simulation;
a system for performing collaborative content creation for 3D assets;
a system for performing one or more deep learning operations;
a system implemented using an edge device;
a system implemented using a robot;
a system for performing one or more generative AI operations;
a system for performing operations using a large language model;
a system for performing operations using one or more vision language models (VLMs);
a system for performing operations using one or more multi-modal language models;
a system for performing one or more conversational AI operations;
a system for generating synthetic data;
a system for presenting at least one of virtual reality content, augmented reality content, or mixed reality content;
a system incorporating one or more virtual machines (VMs);
a system implemented at least partially in a data center; or
a system implemented at least partially using cloud computing resources.

21. A system comprising:
one or more processors to evaluate one or more region of interest (ROI) detection algorithms within a simulation that is rendered using one or more light transport simulation algorithms, the one or more ROI detection algorithms using known object characteristics within a ROI to perform ROI detection.

22. The system of claim 21, wherein the simulation is generated, at least in part, using a three-dimensional (3D) content collaboration platform for 3D assets.

23. The system of claim 22, wherein the 3D content collaboration platform for 3D assets uses OpenUSD.
